(19) United States
(12) Patent Application Publication
(10) Pub. No.: US 2013/0068278 A1
(43) Pub. Date: Mar. 21, 2013

(54) PHOTOVOLTAIC POWER GENERATION APPARATUS, PHOTOVOLTAIC POWER GENERATION APPARATUS ARRAY, WAFER, AND METHOD FOR PRODUCING PHOTOVOLTAIC POWER GENERATION APPARATUS

(71) Applicant: Kohtaroh KATAOKA, Osaka-shi (JP)

(72) Inventor: Kohtaroh KATAOKA, Osaka-shi (JP)

(73) Assignee: Sharp Kabushiki Kaisha, Osaka-shi (JP)

(21) Appl. No.: 13/605,676

(22) Filed: Sep. 6, 2012

(30) Foreign Application Priority Data
Sep. 21, 2011 (JP) 2011-206427

(51) Int. Cl. H01L 31/042; H01L 31/18; H01L 29/06

(52) U.S. Cl. 136/244; 257/618; 438/73; 257/E31.032; 257/E29.022

(57) ABSTRACT

A photovoltaic power generation apparatus includes a first photovoltaic power generation element having a surface in the shape of a triangle, and a second photovoltaic power generation element having a surface in the shape of a trapezoid, which is a polygon not having less sides than a quadrangle. The first photovoltaic power generation element is, for example, an isosceles triangle, and the second photovoltaic power generation element is, for example, an isosceles trapezoid.

### CROSS-REFERENCE TO RELATED APPLICATION

This application claims priority under 35 U.S.C. §119(a) on Patent Application No. 2011-206427 filed in Japan on Sep. 21, 2011, the entire contents of which are herein incorporated by reference.

### TECHNICAL FIELD

The present invention relates to a photovoltaic power generation apparatus including a plurality of photovoltaic power generation elements having surfaces in different shapes, a photovoltaic power generation apparatus array in which a plurality of photovoltaic power generation apparatuses are coupled, a wafer used to produce a photovoltaic power generation apparatus, and a method for producing a photovoltaic power generation apparatus.

### BACKGROUND ART

With an increasing demand for power generation using natural energy (solar light) (solar photovoltaic power generation), development of techniques for solar cells has been facilitated, and various types of solar cells have been proposed. Furthermore, regarding the development, it is an important issue to improve the yield of solar cells from a prepared wafer (the ratio of light-receiving faces of solar cells secured with respect to the area of a wafer as a starting material) in order to save resources, and to improve the filling factor of light-receiving faces of solar cells (the ratio of light-receiving faces with respect to an installation area when solar cells are laid, i.e., the laying ratio) in order to improve the power generation efficiency per unit area in an installation face on which solar cells are installed.

Hereinafter, conventional solar cells and conventional solar cell modules relating to the yield and the filling factor will be described with reference to conventional examples 1 to 3.

FIG. 16A is an explanatory view illustrating a state in which a solar cell 101 according to the conventional example 1 is cut out from a circular shape CCL.

The solar cell 101 is obtained from a single crystal ingot (circular wafer) having a diameter L1 of 200 mm (radius r=100 mm), and is in the shape of a pseudo-square where a length L2 between opposing sides is 156 mm.

The solar cell 101 is formed by cutting off and removing waste regions SC between the solar cell 101 and the circular shape CCL, from the circular shape CCL. That is to say, the solar cell 101 is formed by obtaining a pseudo-square pillar from a single crystal ingot, and slicing the pillar.

An area Ss of the waste region SC is obtained by subtracting an area Sd of a triangle from an area Sf of a sector (the triangle and the waste region SC) indicated by the dashed double dotted line in FIG. 16A. Here, a central angle of the waste region SC=2×arccos( 78/100)=1.35 rad (radians). Accordingly, the area Ss=Sf−Sd=(r²)×(1.35/2)−(½)×(r²)×sin(1.35 rad)=0.188r².

Since an area Sc of the circular shape CCL is πr², the ratio of four areas Sc of the waste regions SC with respect to the area Sc is (0.188r²)×4/πr²=0.239 (23.9%).

That is to say, the solar cell 101 cut out from the circular shape CCL is used only in a ratio of: 100−23.9=76.1(%) with respect to the area Sc of the circular shape CCL. In other words, the yield of the solar cell 101 from the circular shape CCL is 76.1%, and substantially one-quarter of the circular shape is wasted.

FIG. 16B is a schematic plan view showing a planar schematic configuration of a solar cell module 102 in which the solar cells 101 shown in FIG. 16A are arranged in an array.

The solar cell module 102 is formed by laying the solar cells 101. Although the solar cells 101 are apparently arranged with no gap interposed therebetween, interlying spaces 102s are formed between the solar cells 101 since each solar cell is in the shape of a pseudo-square where four corners are missing.

Accordingly, the solar cell module 102 has a filling factor that is lowered due to an area corresponding to the interlying spaces 102s on the installation face, and, therefore, the power generation amount per unit area on the installation face is lowered. As a result, the power generation efficiency is reduced.

Note that, if the solar cell 101 is cut out as a full square from the circular shape CCL, the interlying spaces 102s are not formed on the solar cell module 102. However, the area of the waste regions SC with respect to the area of the circular shape CCL further increases, and, as a result, the yield of the solar cells 101 is further lowered.

FIG. 17A is an explanatory view illustrating a state in which solar cells 103 (a solar cell 103f, a solar cell 103s, and a solar cell 103t) according to the conventional example 2 are obtained by dividing a circular shape.

The solar cells 103 are each configured by the solar cell 103f, the solar cell 103s, and the solar cell 103t that are formed by dividing a circular wafer into three portions along lines corresponding to the diameter. The solar cell 103f is in the shape of a pseudo-rectangle where the width is a length L3 that is the same as the length of the radius, and the solar cell 103s and the solar cell 103t are each a bow-shaped cell where the width is a length L4 that is half the length of the radius.

Since the solar cell 103f, the solar cell 103s, and the solar cell 103t formed by dividing a circular wafer into three portions along lines corresponding to the diameter are used, there is no waste region on the circular wafer. However, each cell partially has an arc-shaped portion, and, therefore, the problem as shown in FIGS. 17B and 17C occurs.

FIG. 17B is a schematic plan view showing a planar schematic configuration of a solar cell module 104 in which the solar cells 103f shown in FIG. 17A are arranged in an array.

The solar cell module 104 is formed by laying the solar cells 103f. However, since the solar cells 103f are each in the shape of a pseudo-rectangle that has not only two parallel sides but also other two sides corresponding to the arc-shaped portions of the circular wafer, when the solar cells are laid such that no gap is interposed therebetween to the extent possible, the solar cells 103f are arranged while being shifted by half the size (half the radius) between rows (or between columns).

Accordingly, for example, when three rows of solar cells 103f are arranged, interlying spaces 104s are formed at both ends of the middle row. The interlying spaces 104s are formed, for example, by the arranged state being shifted between different rows, and the number of solar cells 103f arranged is different by one from the number of those arranged in other rows. That is to say, an area corresponding to one solar cell 103f is an unusable region, and the filling factor is lowered due to an area of the interlying spaces 104s corresponding to the area of the solar cell 103f on the arrangement face. Thus, the power generation amount per unit area on the installation face is lowered, and, as a result, the power generation efficiency is reduced.

FIG. 17C is a schematic plan view showing a planar schematic configuration of a solar cell module 105 in which the solar cells 103s and the solar cells 103t shown in FIG. 17A are arranged in an array.

Since the solar cells 103s and the solar cells 103t have a shape totally different from that of the solar cells 103f, a combination with the solar cells 103f is avoided. That is to say, the solar cell module 105 is formed by laying the solar cells 103s and the solar cells 103t.

However, since the solar cell 103s and the solar cell 103t are each a bow-shaped cell (cell obtained by cutting out part of a circular shape in the shape of an arc), when they are arranged so as to oppose each other, the shape is close to an ellipse. When the solar cell pairs each in the shape close to an ellipse are laid such that no gap is interposed therebetween to the extent possible, the pairs of the solar cells 103s and the solar cells 103t are arranged while being shifted by half the size (half of the half the radius) between rows (or between columns) as in the case of the solar cell module 104.

Accordingly, interlying spaces 105s are formed at both ends of a row. That is to say, the problem as in the solar cell module 104 occurs. Furthermore, gaps due to arc-shaped portions are formed between the solar cells 103s and the solar cells 103t including the arc-shaped portions.

As described above, it is difficult to combine the solar cells 103s and the solar cells 103t with the solar cells 103f. Meanwhile, unless the solar cell modules 105 configured by a combination of the solar cells 103s and the solar cells 103t are formed in the same number as that of solar cell modules 104, the solar cells 103s and the solar cells 103t are wasted, which restricts the production.

For example, if a predetermined number of solar cell modules 104 are produced, a predetermined number of solar cells 103s and solar cells 103t for forming into the solar cell modules 105 are also formed regardless of the level of demand for the solar cell modules 105. If the demand for the solar cell modules 105 is low, the solar cells 103s and the solar cells 103t are supplied too much and wasted.

Furthermore, the solar cell module 104 in which the solar cells 103f are arranged and the solar cell module 105 in which the solar cells 103s and the solar cells 103t are arranged have mutually different electrical specifications, and, therefore, it is difficult to ensure the consistency in output characteristics.

For example, connecting the solar cell module 104 and the solar cell module 105 in series means series connection of modules having mutually different output currents, and, therefore, efficient power generation cannot be performed. Accordingly, when forming a solar photovoltaic power generation system using a plurality of modules, these modules cannot be freely arranged in a mixed manner regardless of their types, and their applications are limited considering their electrical specifications and module sizes. Thus, the demand balance for these modules cannot be always achieved. If the demand balance cannot be achieved, the solar cells are supplied too much and wasted, which restricts the production.

FIG. 18A is an explanatory view illustrating a state in which solar cells 106 (a solar cell 106c, solar cells 106f, and solar cells 106s) according to the conventional example 3 are obtained by dividing a circular shape.

The solar cells 106 are each configured by the solar cell 106c obtained by dividing a circular wafer into a square inscribed in the circumference, and bow-shaped cells (two solar cells 106f and two solar cells 106s) that are formed in regions between the square and the circular shape.

Since the square solar cell 106c and the bow-shaped solar cells 106f and solar cells 106s are used, there is no waste region on the circular wafer.

FIG. 18B is a schematic plan view showing a planar schematic configuration of a solar cell module 107 in which the solar cells 106s shown in FIG. 18A are arranged in an array.

The solar cell module 107 is formed by laying the solar cells 106s. However, since the solar cells 106s are each a bow-shaped cell, interlying spaces 107s are formed due to the arc-shaped portions, and the problem as in the conventional example 2 (the solar cell module 105) occurs.

Note that, for example, the technique corresponding to the conventional example 1 is disclosed in Patent Document 1, the technique corresponding to the conventional example 2 is disclosed in Patent Document 2, and the technique corresponding to the conventional example 3 is disclosed in Patent Document 3.
[Patent Document 1] JP 2011-77362A
[Patent Document 2] Domestic re-publication of WO2003/073516
[Patent Document 3] JP 2006-73985A

### SUMMARY OF INVENTION

As described above, in a conventional solar cell (cell and module), if the yield from a circular shape is improved when forming solar cells, the filling factor of solar cells in a solar cell module in which a plurality of solar cells are arranged is lowered, and, furthermore, if the filling factor of solar cells is improved, the yield of solar cells is lowered. That is to say, both a high yield and a high filling factor cannot be sufficiently achieved at the same time.

The present invention was made in view of these circumstances, and it provides a photovoltaic power generation apparatus in which the yield with respect to a circular wafer (circular shape) as a starting material is high and the filling factor of the formed photovoltaic power generation apparatuses with respect to the installation area is high, by cutting out the first photovoltaic power generation element in the shape of a triangle and the second photovoltaic power generation element in the shape of a polygon not having less sides than a quadrangle (e.g., trapezoid, pentagon, or hexagon) from a circular wafer.

Furthermore, it is another object of the present invention to provide a photovoltaic power generation apparatus array in which the laying ratio is high and high-capacity photovoltaic power generation with good yield can be achieved, by coupling a plurality of photovoltaic power generation apparatuses according to the present invention.

Furthermore, it is another object of the present invention to provide a wafer that allows a photovoltaic power generation apparatus having an improved yield from a wafer (circular shape) and an improved laying ratio on the installation face to be produced at a high productivity, by using a wafer in a regular octagonal shape cut out from a circular shape.

Furthermore, it is another object of the present invention to provide a photovoltaic power generation apparatus production method that allows a photovoltaic power generation apparatus having a high yield with respect to the circular shape and a high laying ratio to be precisely and easily produced, by forming a photovoltaic power generation apparatus by dividing a regular octagonal wafer.

Furthermore, it is another object of the present invention to provide a photovoltaic power generation apparatus production method that allows a photovoltaic power generation apparatus having an improved yield and a high laying ratio to be precisely and easily produced, by forming a photovoltaic power generation apparatus by dividing a circular wafer.

The present invention is directed to a photovoltaic power generation apparatus, including: a first photovoltaic power generation element having a surface in a shape of a triangle; and a second photovoltaic power generation element having a surface in a shape of a polygon not having less sides than a quadrangle.

Thus, since the photovoltaic power generation apparatus according to the present invention is configured by a combination of the first photovoltaic power generation element having a surface in the shape of a triangle and the second photovoltaic power generation element having a surface in the shape of a polygon not having less sides than a quadrangle, the first photovoltaic power generation element and the second photovoltaic power generation element having surfaces in different shapes can be arranged such that no gap is interposed therebetween. Thus, the filling factor (laying ratio) of the light-receiving faces on the installation face can be increased by laying the first photovoltaic power generation element and the second photovoltaic power generation element having surfaces in different shapes, and the yield with respect to the circular shape can be improved.

In the photovoltaic power generation apparatus according to the present invention, it is preferable that the first photovoltaic power generation element and the second photovoltaic power generation element are combined such that the number of elements of one of the types is the same as the number of elements of the other type, or combined such that the number of elements of one of the types is an integer multiple of the number of elements of the other type, forming a rectangle.

Thus, since the photovoltaic power generation apparatus according to the present invention is in the shape of a rectangle configured by a combination of the first photovoltaic power generation element and the second photovoltaic power generation element having surfaces in different shapes, the laying ratio with respect to a necessary area of the light-receiving faces can be improved by laying the first photovoltaic power generation element and the second photovoltaic power generation element with no gap interposed therebetween.

In the photovoltaic power generation apparatus according to the present invention, it is preferable that the first photovoltaic power generation element and the second photovoltaic power generation element are connected in parallel such that the number of elements of one of the types is the same as or is an integer multiple of the number of elements of the other type.

Thus, in the photovoltaic power generation apparatus according to the present invention, since the first photovoltaic power generation element and the second photovoltaic power generation element are connected in parallel such that the number of elements of one of the types is the same as the number of elements of the other type or such that the number of elements of one of the types is an integer multiple of the number of elements of the other type, even when the first photovoltaic power generation element and the second photovoltaic power generation element having different shapes (different light-receiving faces) are combined, the power generation amount according to the sum of their respective light-receiving areas can be obtained.

In the photovoltaic power generation apparatus according to the present invention, it is preferable that the triangle has at least one interior angle that is (⅛)π radians, and the polygon has at least one interior angle that is (⅜)π radians or (¾)π radians, and the interior angle that is (⅛)π radians of the first photovoltaic power generation element and the interior angle that is (⅜)π radians or (¾)π radians of the second photovoltaic power generation element are arranged adjacent to each other.

Thus, in the photovoltaic power generation apparatus according to the present invention, since the interior angle that is (⅛)π radians of the first photovoltaic power generation element and the interior angle that is (⅜)π radians (or (¾)π radians) of the second photovoltaic power generation element are arranged adjacent to each other, (½)π radians (π radians) can be obtained. Thus, a precise rectangle can be configured by a combination of the first photovoltaic power generation element and the second photovoltaic power generation element.

The photovoltaic power generation apparatus according to the present invention may be configured such that the triangle is an isosceles triangle, and the polygon is a trapezoid.

Thus, since the photovoltaic power generation apparatus according to the present invention is configured by a combination of isosceles triangles and trapezoids, if the trapezoids are, for example, isosceles trapezoids, the rectangle can be precisely configured by a combination of two first photovoltaic power generation elements and two second photovoltaic power generation elements, and, if the trapezoids are, for example, right-angled trapezoids (trapezoids in which an interior angle between one leg and the lower base is a right angle), the rectangle can be precisely configured by a combination of one (or two) first photovoltaic power generation element and two (or four) second photovoltaic power generation elements, and, therefore, an effective laying operation can be performed.

The photovoltaic power generation apparatus according to the present invention may be configured such that the triangle is a right-angled triangle, and the polygon is a right-angled trapezoid in which an interior angle between one leg and a lower base is a right angle.

Accordingly, since the photovoltaic power generation apparatus according to the present invention is configured by a combination of a right-angled triangle and a right-angled trapezoid in which an interior angle between one leg and the lower base (and the upper base) is a right angle, the rectangle can be configured by a combination of one (or two or four) first photovoltaic power generation element and one (or two or four) second photovoltaic power generation element, and, therefore, a highly applicable and more effective laying operation can be performed using a large number of rectangles.

The photovoltaic power generation apparatus according to the present invention may be configured such that the triangle includes the right-angled triangle and a symmetrical triangle, which is mirror symmetric to the right-angled triangle, and the polygon includes the right-angled trapezoid and a symmetrical trapezoid, which is mirror symmetric to the right-angled trapezoid.

Thus, since the photovoltaic power generation apparatus according to the present invention is configured by a combination of a right-angled triangle, a symmetrical triangle, which is mirror symmetric to the right-angled triangle, a right-angled trapezoid, and a symmetrical trapezoid, which is mirror symmetric to the right-angled trapezoid, the photovoltaic power generation apparatus includes a rectangle configured by the right-angled triangle and the right-angled trapezoid and a rectangle configured by the symmetrical triangle and the symmetrical trapezoid. Thus, the symmetric properties in arrangement of the first photovoltaic power generation element and the second photovoltaic power generation element can be improved, and the unevenness in the power generation characteristics can be alleviated.

In the photovoltaic power generation apparatus according to the present invention, it is preferable that the first photovoltaic power generation element and the second photovoltaic power generation element are of a back-face electrode type, and connected to a wiring board.

Thus, in the photovoltaic power generation apparatus according to the present invention, since back-face electrodes of the first photovoltaic power generation element and the second photovoltaic power generation element are connected to a wiring board, the element surface shape is applied to the light-receiving face as it is, and high power generation efficiency and easy handling can be achieved.

Furthermore, the present invention is directed to a photovoltaic power generation apparatus array in which a plurality of photovoltaic power generation apparatuses are connected in an array, wherein the photovoltaic power generation apparatuses are each the photovoltaic power generation apparatus according to the present invention.

Thus, in the photovoltaic power generation apparatus array according to the present invention, since a plurality of photovoltaic power generation apparatuses each in the shape of a rectangle are connected in an array, the laying ratio is high, and high-capacity photovoltaic power generation with good yield can be easily achieved.

Furthermore, the present invention is directed to a wafer having a surface in a shape of a regular octagon cut out from a circular shape.

Thus, since the wafer according to the present invention is cut out in the shape of a regular octagon from a circular shape, the waste regions of the wafer (the waste regions between the circumference of the circular shape and the regular octagonal shape) have been removed in advance, and the combination of the first photovoltaic power generation element in the shape of a triangle and the second photovoltaic power generation element in the shape of a trapezoid can be easily and precisely cut out. Thus, a photovoltaic power generation apparatus in which the yield from a wafer (circular shape) and the laying ratio on the installation face are improved can be produced at a high productivity.

Furthermore, the present invention is directed to a method for producing the photovoltaic power generation apparatus according to the present invention in which a regular octagonal shape is obtained by virtually combining a first photovoltaic power generation element having a surface in a shape of a triangle and a second photovoltaic power generation element having a surface in a shape of a polygon not having less sides than a quadrangle, wherein the first photovoltaic power generation element and the second photovoltaic power generation element are formed by dividing a wafer in the regular octagonal shape that has been obtained by removing in advance waste regions between the regular octagonal shape inscribed in a circular shape and the circular shape.

Thus, with the method for producing a photovoltaic power generation apparatus according to the present invention, the first photovoltaic power generation element and the second photovoltaic power generation element are formed by dividing the regular octagonal wafer that has been obtained by removing in advance the waste regions between the circumference of the circular shape and the regular octagonal shape inscribed in that circumference, and, therefore, the waste regions do not have to be removed in each wafer. Furthermore, the division lines demarcated by vertices clearly indicate cutoffs lines, and, therefore, a photovoltaic power generation apparatus in which the yield with respect to the circular shape and the laying ratio are high can be precisely and easily produced.

Furthermore, the present invention is directed to a method for producing the photovoltaic power generation apparatus according to the present invention in which a regular octagonal shape is obtained by virtually combining a first photovoltaic power generation element having a surface in a shape of a triangle and a second photovoltaic power generation element having a surface in a shape of a polygon not having less sides than a quadrangle, wherein the first photovoltaic power generation element and the second photovoltaic power generation element are formed by dividing a wafer in a circular shape based on the regular octagonal shape inscribed in the circular shape.

Thus, with the method for producing a photovoltaic power generation apparatus according to the present invention, the first photovoltaic power generation element and the second photovoltaic power generation element are formed by dividing the circular wafer based on the regular octagonal shape inscribed in the circumference of the circular shape. Thus, a photovoltaic power generation apparatus in which the yield is improved by suppressing the area of the waste regions between the circumference and the regular octagonal shape, and the laying ratio is high can be precisely and easily produced.

### BRIEF DESCRIPTION OF DRAWINGS

FIG. 1A is a schematic plan view showing a planar schematic configuration of a photovoltaic power generation apparatus according to Embodiment 1 of the present invention.

FIG. 1B is a basic configuration diagram showing a basic configuration of a connection form of a first photovoltaic power generation element and a second photovoltaic power generation element forming the photovoltaic power generation apparatus shown in FIG. 1A.

FIG. 2 is an explanatory view illustrating a state in which the first photovoltaic power generation elements and the second photovoltaic power generation elements forming the photovoltaic power generation apparatus shown in FIG. 1A are obtained by dividing a circular shape along division lines.

FIG. 3 is a schematic plan view showing a planar schematic configuration of a photovoltaic power generation apparatus array according to Embodiment 2 of the present invention.

FIG. 4 is a schematic plan view showing a planar schematic configuration of a photovoltaic power generation apparatus according to Embodiment 3 of the present invention.

FIG. 5 is an explanatory view illustrating a state in which the first photovoltaic power generation elements and the second photovoltaic power generation elements forming the photovoltaic power generation apparatus shown in FIG. 4 are obtained by dividing a circular shape along the division lines.

FIG. 6A is a schematic plan view showing a planar schematic configuration of a photovoltaic power generation apparatus according to Embodiment 4 of the present invention.

FIG. 6B is a schematic plan view showing a planar schematic configuration of a photovoltaic power generation apparatus according to Embodiment 4 of the present invention.

FIG. 6C is a schematic plan view showing a planar schematic configuration of a photovoltaic power generation apparatus according to Embodiment 4 of the present invention.

FIG. 6D is a schematic plan view showing a planar schematic configuration of a photovoltaic power generation apparatus according to Embodiment 4 of the present invention.

FIG. 7 is an explanatory view illustrating a state in which the first photovoltaic power generation elements and the second photovoltaic power generation element forming a photovoltaic power generation apparatus according to Embodiment 5 of the present invention are obtained by dividing a circular shape along the division lines.

FIG. 8 is a schematic plan view showing a planar schematic configuration of a photovoltaic power generation apparatus configured by a combination of the first photovoltaic power generation elements and the second photovoltaic power generation element obtained by the division shown in FIG. 7.

FIG. 9 is an explanatory view illustrating a state in which the first photovoltaic power generation elements and the second photovoltaic power generation elements forming a photovoltaic power generation apparatus according to Embodiment 5 of the present invention are obtained by dividing a circular shape along the division lines.

FIG. 10 is a schematic plan view showing a planar schematic configuration of a photovoltaic power generation apparatus configured by a combination of the first photovoltaic power generation elements and the second photovoltaic power generation elements obtained by the division shown in FIG. 9.

FIG. 11 is an explanatory view illustrating a state in which the first photovoltaic power generation elements and the second photovoltaic power generation elements forming a photovoltaic power generation apparatus according to Embodiment 5 of the present invention are obtained by dividing a circular shape along the division lines.

FIG. 12 is a schematic plan view showing a planar schematic configuration of a photovoltaic power generation apparatus configured by a combination of the first photovoltaic power generation elements and the second photovoltaic power generation elements obtained by the division shown in FIG. 11.

FIG. 13 is an explanatory view illustrating a state in which the first photovoltaic power generation elements and the second photovoltaic power generation elements forming a photovoltaic power generation apparatus according to Embodiment 5 of the present invention are obtained by dividing a circular shape along the division lines.

FIG. 14 is a schematic plan view showing a planar schematic configuration of a photovoltaic power generation apparatus configured by a combination of the first photovoltaic power generation elements and the second photovoltaic power generation elements obtained by the division shown in FIG. 13.

FIG. 15 is a table that lists the contents of the combinations of triangles and polygons according to Embodiments 1 to 5.

FIG. 16A is an explanatory view illustrating a state in which a solar cell according to the conventional example 1 is cut out from a circular shape.

FIG. 16B is a schematic plan view showing a planar schematic configuration of a solar cell module in which the solar cells shown in FIG. 16A are arranged in an array.

FIG. 17A is an explanatory view illustrating a state in which solar cells according to the conventional example 2 are obtained by dividing a circular shape.

FIG. 17B is a schematic plan view showing a planar schematic configuration of a solar cell module in which the solar cells shown in FIG. 17A are arranged in an array.

FIG. 17C is a schematic plan view showing a planar schematic configuration of a solar cell module in which the solar cells shown in FIG. 17A are arranged in an array.

FIG. 18A is an explanatory view illustrating a state in which solar cells according to the conventional example 3 are obtained by dividing a circular shape.

FIG. 18B is a schematic plan view showing a planar schematic configuration of a solar cell module in which the solar cells shown in FIG. 18A are arranged in an array.

### DESCRIPTION OF EMBODIMENTS

Hereinafter, embodiments of the present invention will be described with reference to the drawings.

### Embodiment 1

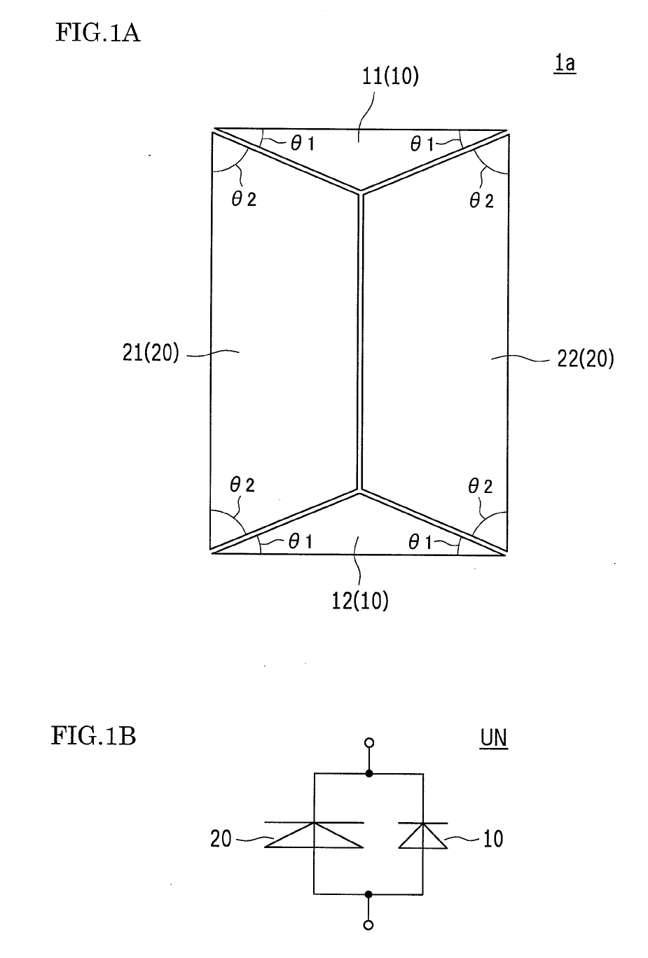

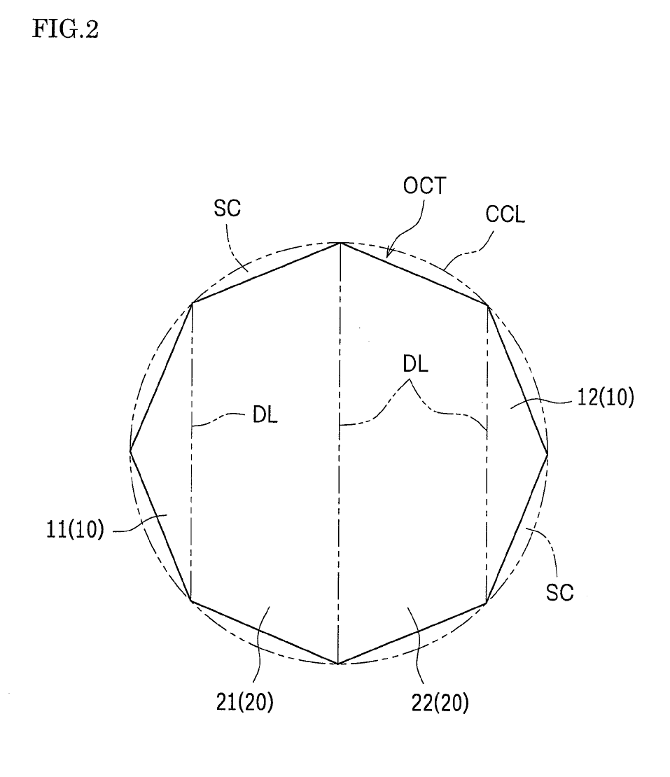

Hereinafter, a photovoltaic power generation apparatus 1a, a method for producing the photovoltaic power generation apparatus 1a, and a wafer used to produce the photovoltaic power generation apparatus 1a according to this embodiment will be described with reference to FIGS. 1A to 2.

FIG. 1A is a schematic plan view showing a planar schematic configuration of the photovoltaic power generation apparatus 1a according to Embodiment 1 of the present invention.

The photovoltaic power generation apparatus 1a according to this embodiment includes first photovoltaic power generation elements 10 (an isosceles triangle 11 and an isosceles triangle 12 in this embodiment) each having a surface in the shape of a triangle, and second photovoltaic power generation elements 20 (an isosceles trapezoid 21 and an isosceles trapezoid 22 in this embodiment) each having a surface in the shape of a trapezoid. Note that a trapezoid (isosceles trapezoid) according to this embodiment is a type of a polygon not having less sides than a quadrangle.

Accordingly, since the photovoltaic power generation apparatus 1a is configured by a combination of the first photovoltaic power generation elements 10 (the isosceles triangle 11 and the isosceles triangle 12) each having a surface in the shape of a triangle and the second photovoltaic power generation elements 20 (the isosceles trapezoid 21 and the isosceles trapezoid 22) each having a surface in the shape of a trapezoid, which is a polygon not having less sides than a quadrangle, the first photovoltaic power generation elements 10 and the second photovoltaic power generation elements 20 having surfaces in different shapes can be arranged such that a gap is hard to be interposed therebetween. For example, the first photovoltaic power generation elements 10 and the second photovoltaic power generation elements 20 can be arranged with a minimum gap interposed therebetween that does not allow the photovoltaic power generation elements to be electrically connected to each other, and there is no waste gap. Thus, the filling factor (laying ratio) of the light-receiving faces on the installation face can be increased by laying the first photovoltaic power generation elements 10 and the second photovoltaic power generation elements 20 having surfaces in different shapes, and the yield with respect to the circular shape can be improved. Note that an improvement in the yield will be described in detail with reference to FIG. 2.

Furthermore, the photovoltaic power generation apparatus 1a is in the shape of a rectangle, wherein the first photovoltaic power generation elements 10 include two triangles, namely the isosceles triangle 11 and the isosceles triangle 12, and the second photovoltaic power generation elements 20 include two trapezoids, namely the isosceles trapezoid 21 and the isosceles trapezoid 22. That is to say, in the photovoltaic power generation apparatus 1a, the same number of first photovoltaic power generation elements 10 and second photovoltaic power generation elements 20 are combined, forming a rectangle.

Accordingly, since the photovoltaic power generation apparatus 1a is in the shape of a rectangle configured by a combination of the first photovoltaic power generation elements 10 (triangles) and the second photovoltaic power generation elements 20 (trapezoids) having surfaces in different shapes, the laying ratio with respect to a necessary area of the light-receiving faces can be improved by laying the first photovoltaic power generation elements 10 and the second photovoltaic power generation elements 20 with substantially no gap interposed therebetween. The gaps between the photovoltaic power generation elements (between the first photovoltaic power generation elements 10, between the second photovoltaic power generation elements 20, and between the first photovoltaic power generation element 10 and the second photovoltaic power generation element 20) can be minimum gaps, for example, that do not allow the photovoltaic power generation elements to be electrically connected to each other, and there is no waste gap depending on the shape of the photovoltaic power generation elements.

As described above, in the photovoltaic power generation apparatus 1a, the triangles are isosceles triangles (specifically, the isosceles triangle 11 and the isosceles triangle 12) and the trapezoids, which are each a polygon not having less sides than a quadrangle, are isosceles trapezoids (specifically, the isosceles trapezoid 21 and the isosceles trapezoid 22).

Accordingly, since the photovoltaic power generation apparatus 1a is configured by a combination of isosceles triangles (the isosceles triangle 11 and the isosceles triangle 12) and isosceles trapezoids (the isosceles trapezoid 21 and the isosceles trapezoid 22), the rectangle can be precisely configured by a combination of two first photovoltaic power generation elements 10 (the isosceles triangle 11 and the isosceles triangle 12) and two second photovoltaic power generation elements 20 (the isosceles trapezoid 21 and the isosceles trapezoid 22), and an effective laying operation can be performed.

In this example, one first photovoltaic power generation element 10 (e.g., the isosceles triangle 11) and one second photovoltaic power generation element 20 (e.g., the isosceles trapezoid 21) are collectively taken as a minimum connection unit UN (see FIG. 1B), and two pairs of the first photovoltaic power generation elements 10 and the second photovoltaic power generation elements 20 (minimum connection units UN) are arranged in the entire rectangle. Thus, such minimum connection units UN (one first photovoltaic power generation element 10 and one second photovoltaic power generation element 20) may be further connected in series or in parallel, and, therefore, a free connection form according to the needs can be obtained.

Since the isosceles triangle 11 and the isosceles triangle 12 each have two equal sides, interior angles θ1 formed by the bottom side and two oblique sides are equal to each other, that is, two equal interior angles θ1 are present. Since the isosceles trapezoid 21 and the isosceles trapezoid 22 each have legs with equal lengths, interior angles θ2 formed by the lower base and the legs are equal to each other, that is, two equal interior angles θ₂ are present. Accordingly, since both the triangles (the isosceles triangle 11 and the isosceles triangle 12) and the trapezoids (the isosceles trapezoid 21 and the isosceles trapezoid 22) have symmetrical shapes, for example, in a state where the arrangement of the isosceles triangle 11 and the isosceles triangle 12 is fixed, the isosceles trapezoid 21 and the isosceles trapezoid 22 may be switched.

The interior angle θ1 is (⅛)π radians, and the interior angle θ2 is (⅜)π radians. When the interior angle θ1 and the interior angle θ2 are combined, ( 4/8)π radians is obtained, forming a right angle. Accordingly, the shape of the outer periphery of the photovoltaic power generation apparatus 1a is rectangular.

That is to say, in this embodiment, the triangles (the isosceles triangle 11 and the isosceles triangle 12) each have at least one interior angle θ1 that is (⅛)π radians, and the trapezoids (the isosceles trapezoid 21 and the isosceles trapezoid 22) each have at least one interior angle θ2 that is (⅜)π radians, where the interior angle θ1 that is (⅛)π radians of the first photovoltaic power generation element 10 (the isosceles triangle 11 and the isosceles triangle 12) and the interior angle θ2 that is (⅜)π radians of the second photovoltaic power generation element 20 (the isosceles trapezoid 21 and the isosceles trapezoid 22) are arranged adjacent to each other.

Accordingly, in the photovoltaic power generation apparatus 1a, since the interior angle θ1 that is (⅛)π radians of the first photovoltaic power generation element 10 (the isosceles triangle 11 and the isosceles triangle 12) and the interior angle θ2 that is (⅜)π radians of the second photovoltaic power generation element 20 (the isosceles trapezoid 21 and the isosceles trapezoid 22) are arranged adjacent to each other, (½)π radians can be obtained. Thus, a precise rectangle can be configured by a combination of the first photovoltaic power generation elements 10 (isosceles triangles) and the second photovoltaic power generation elements 20 (trapezoids).

Note that the actual element shape is preferably set such that the surface shape is applied to the light-receiving face as it is. Accordingly, in the first photovoltaic power generation element 10 and the second photovoltaic power generation element 20, electrodes (not shown) for extracting a photoelectromotive force are formed on back faces on the side opposite the light-receiving faces, and the electrodes (back-face electrodes) are connected to a wiring board (not shown) disposed on the back faces. That is to say, in the photovoltaic power generation apparatus 1a, the first photovoltaic power generation element 10 and the second photovoltaic power generation element 20 are of a back-face electrode type, and connected to the wiring board (not shown).

Accordingly, in the photovoltaic power generation apparatus 1a, since the back-face electrodes of the first photovoltaic power generation element 10 (the isosceles triangle 11 and the isosceles triangle 12) and the second photovoltaic power generation element 20 (the isosceles trapezoid 21 and the isosceles trapezoid 22) are connected to the wiring board, the element surface shape is applied to the light-receiving face as it is, and high power generation efficiency and easy handling can be achieved.

Note that the first photovoltaic power generation element 10 and the second photovoltaic power generation element 20 of a back-face electrode type respectively include a first electrode having a first polarity and a second electrode having a second polarity on the back faces on the side opposite the light-receiving faces. Furthermore, appropriate wiring patterns corresponding to the first electrode and the second electrode are formed on the wiring board. The shape of the first electrode and the second electrode and the shape of the wiring patterns can be set as appropriate, and, therefore, a description thereof has been omitted.

FIG. 1B is a basic configuration diagram showing a basic configuration of a connection form of the first photovoltaic power generation element 10 and the second photovoltaic power generation element 20 forming the photovoltaic power generation apparatus 1a shown in FIG. 1A. In order to indicate that the amount of current generated by the second photovoltaic power generation element 20 is larger than that by the first photovoltaic power generation element 10, the second photovoltaic power generation element 20 is shown as being larger than the first photovoltaic power generation element 10.

It is preferable that a parallel circuit in which one first photovoltaic power generation element 10 in the shape of a triangle and one second photovoltaic power generation element 20 in the shape of a trapezoid are connected in parallel is taken as the minimum connection unit UN. That is to say, it is preferable that, as shown in the drawing, the minimum connection unit UN is configured by one first photovoltaic power generation element 10 and one second photovoltaic power generation element 20 connected in parallel.

For example, if the first photovoltaic power generation element 10 and the second photovoltaic power generation element 20 are made of silicon single crystal, all of the isosceles triangle 11, the isosceles triangle 12, the isosceles trapezoid 21, and the isosceles trapezoid 22 generate the same voltage but have different light-receiving faces, and, therefore, a current generated by the first photovoltaic power generation element 10 (the isosceles triangle 11 and the isosceles triangle 12) is different from that by the second photovoltaic power generation element 20 (the isosceles trapezoid 21 and the isosceles trapezoid 22).

Accordingly, it is not preferable that the first photovoltaic power generation element 10 and the second photovoltaic power generation element 20 are simply connected in series, because a current generated by the first photovoltaic power generation element 10 having a small light-receiving face restricts a current that flows through the photovoltaic power generation apparatus 1a.

That is to say, the first photovoltaic power generation element 10 (the isosceles triangle 11 and the isosceles triangle 12) and the second photovoltaic power generation element 20 (the isosceles trapezoid 21 and the isosceles trapezoid 22) have mutually different areas, and, therefore, obtained currents are different from each other. Accordingly, it is preferable that the minimum connection unit UN is configured by one first photovoltaic power generation element 10 and one second photovoltaic power generation element 20 connected in parallel.

In other words, it is preferable that the minimum connection unit UN is configured by one triangle (the isosceles triangle 11 or the isosceles triangle 12) and one trapezoid (the isosceles trapezoid 21 or the isosceles trapezoid 22) connected in parallel. For example, when the isosceles triangle 11 and the isosceles trapezoid 21 are connected in parallel, and the isosceles triangle 12 and the isosceles trapezoid 22 are connected in parallel, the problem caused by an unevenness in generated currents due to an unevenness in areas can be solved.

It is possible to freely select whether to further connect such minimum connection units UN in parallel or in series, and, therefore, connection according to the needs can be obtained. For example, a parallel connection pair (the minimum connection unit UN) configured by the isosceles triangle 11 and the isosceles trapezoid 21 and a parallel connection pair (the minimum connection unit UN) configured by the isosceles triangle 12 and the isosceles trapezoid 22 may be connected in series. Furthermore, a parallel connection pair (the minimum connection unit UN) configured by the isosceles triangle 11 and the isosceles trapezoid 21 and a parallel connection pair (the minimum connection unit UN) configured by the isosceles triangle 12 and the isosceles trapezoid 22 may be connected in parallel.

As described above, in the photovoltaic power generation apparatus 1a, it is preferable that the same number of first photovoltaic power generation elements 10 (the isosceles triangles 11 or the isosceles triangles 12) and second photovoltaic power generation elements 20 (the isosceles trapezoids 21 or the isosceles trapezoids 22) are connected in parallel.

Accordingly, in the photovoltaic power generation apparatus 1a, since the same number of first photovoltaic power generation elements 10 and second photovoltaic power generation elements 20 are connected in parallel, even when the first photovoltaic power generation element 10 and the second photovoltaic power generation element 20 having different shapes (different light-receiving faces) are combined, the power generation amount according to the sum of their respective light-receiving areas can be obtained.

FIG. 2 is an explanatory view illustrating a state in which the first photovoltaic power generation elements 10 and the second photovoltaic power generation elements 20 forming the photovoltaic power generation apparatus 1a shown in FIG. 1A are obtained by dividing a circular shape CCL along division lines DL.

Hereinafter, a method for forming the first photovoltaic power generation elements 10 and the second photovoltaic power generation elements 20 via a regular octagonal shape OCT from the circular shape CCL (method for producing the photovoltaic power generation apparatus la) will be described.

The photovoltaic power generation apparatus 1a is cut out from a wafer (e.g., the wafer in the circular shape CCL) having undergone production processes such as an impurity diffusion process and an electrode formation process. For example, the regular octagonal shape OCT included (inscribed) in the circular shape CCL is set (assumed), and the regular octagonal shape OCT is divided into two portions along the center division line DL that divides the regular octagonal shape OCT in half, forming pentagons. Then, the two formed (assumed) pentagons are respectively divided along the division lines DL and cut into two second photovoltaic power generation elements 20 (the isosceles trapezoid 21 and the isosceles trapezoid 22) that are plane symmetric to each other. The remaining portions after cutting out the second photovoltaic power generation elements 20 are used as the first photovoltaic power generation elements 10. Note that, at the time of division, the cutting may be started from any division line DL. That is to say, the remaining portions after cutting out the first photovoltaic power generation elements 10 may be used as the second photovoltaic power generation elements 20.

Furthermore, when cutting out the first photovoltaic power generation elements 10 and the second photovoltaic power generation elements 20 from the wafer, there are methods in which the elements are cut out from the wafer in the regular octagonal shape OCT that has been obtained by removing in advance the waste regions SC between the circular shape CCL and the regular octagonal shape OCT (a production method 1), and in which the elements are cut out from the circular shape CCL and the waste regions SC are removed (a production method 2).

Hereinafter, the methods 1 and 2 for producing the photovoltaic power generation apparatus 1a will be specifically described. Note that the wafer in the regular octagonal shape OCT is formed by removing in advance the waste regions SC from the circular shape CCL (cylindrical ingot stage), thereby forming the pillar in the regular octagonal shape OCT (ingot stage), and then slicing the pillar.

Hereinafter, the production method 1 in which the regular octagonal shape OCT has been formed in advance in the wafer stage will be described.

The method (the production method 1) for producing the photovoltaic power generation apparatus 1a according to this embodiment is a method for producing the photovoltaic power generation apparatus 1a in which the regular octagonal shape OCT is obtained by virtually combining a plurality of first photovoltaic power generation elements 10 (the isosceles triangle 11 and the isosceles triangle 12) each having a surface in the shape of a triangle and a plurality of second photovoltaic power generation elements 20 (the isosceles trapezoid 21 and the isosceles trapezoid 22) each having a surface in the shape of a trapezoid, which is a polygon not having less sides than a quadrangle, wherein the first photovoltaic power generation elements 10 (the isosceles triangle 11 and the isosceles triangle 12) and the second photovoltaic power generation elements 20 (the isosceles trapezoid 21 and the isosceles trapezoid 22) are formed by dividing the wafer in the regular octagonal shape OCT that has been obtained by removing in advance the waste regions SC between the regular octagonal shape OCT inscribed in the circular shape CCL and the circular shape CCL.

Thus, according to the method (the production method 1) for producing the photovoltaic power generation apparatus 1a, the first photovoltaic power generation elements 10 (the isosceles triangle 11 and the isosceles triangle 12) and the second photovoltaic power generation elements 20 (the isosceles trapezoid 21 and the isosceles trapezoid 22) are formed by dividing the wafer in the regular octagonal shape OCT that has been obtained by removing in advance the waste regions SC between the circumference of the circular shape CCL and the regular octagonal shape OCT inscribed in that circumference, and, therefore, the waste regions SC do not have to be removed in each wafer. Furthermore, the division lines DL demarcated by vertices clearly indicate cutoffs lines, and, therefore, a photovoltaic power generation apparatus 1a in which the yield with respect to the circular shape and the laying ratio are high can be precisely and easily produced.

When the division line DL that links two vertices among eight vertices and divides the regular octagonal shape OCT in half is, for example, perpendicularly set and taken as a perpendicular line, the regular octagonal shape OCT is divided into bilaterally symmetrical pentagons (a pentagon configured by the isosceles triangle 11 and the isosceles trapezoid 21 and a pentagon configured by the isosceles triangle 12 and the isosceles trapezoid 22), and the pentagons are further divided into the first photovoltaic power generation elements 10 and the second photovoltaic power generation elements 20.

According to the method 1 for producing the photovoltaic power generation apparatus 1a, in the ingot stage, the waste regions SC in the circumferential portion of the cylindrical shape (the circular shape CCL) are removed in advance, forming the pillar in the regular octagonal shape OCT, and the pillar in the regular octagonal shape OCT is sliced, forming the wafer in the regular octagonal shape OCT. Accordingly, the wafer in the regular octagonal shape OCT is subjected to the production process.

That is to say, the wafer loaded into the production process is a wafer obtained by forming the regular octagonal shape OCT (pillar) in advance in the ingot stage and slicing the pillar in advance into the wafer in the regular octagonal shape OCT. When the wafer in the regular octagonal shape OCT is used, the waste regions SC are recovered before loading the wafer into the production process, and, therefore, the recovery efficiency can be improved.

Furthermore, since the wafer having undergone the production process has been shaped in advance into the regular octagonal shape OCT, the waste regions SC in the circumferential portion of the circular shape CCL (in the case of a circular wafer) do not have to be removed in each wafer, and the division process (the process that cuts out the first photovoltaic power generation elements 10 and the second photovoltaic power generation elements 20) can be simplified.

Furthermore, the wafer according to this embodiment has a surface in the regular octagonal shape OCT cut out from the circular shape CCL.

Accordingly, since the wafer (the regular octagonal shape OCT) according to this embodiment has been cut out from the circular shape CCL as a wafer in the regular octagonal shape OCT, the waste regions SC (the waste regions SC between the circumference of the circular shape CCL and the regular octagonal shape OCT) of the wafer have been removed in advance, and the combination of the first photovoltaic power generation elements 10 each in the shape of a triangle and the second photovoltaic power generation elements 20 each in the shape of a trapezoid can be easily and precisely cut out. Thus, a photovoltaic power generation apparatus 1a in which the yield from the wafer and the laying ratio on the installation face are improved can be produced at a high productivity.

Note that it is preferable that the wafer in the regular octagonal shape OCT is a single crystal wafer formed as an ingot. Specifically, when this method is applied to a single crystal wafer (single crystal silicon wafer), a significant effect is achieved. Since the wafer is in the regular octagonal shape OCT, the processing apparatus has a structure set according to the regular octagonal shape OCT in advance.

Next, the production method 2 in which the first photovoltaic power generation elements 10 and the second photovoltaic power generation elements 20 are formed by cutting (dividing) the circular shape CCL (circular wafer) will be described.

The method (the production method 2) for producing the photovoltaic power generation apparatus 1a according to this embodiment is a method for producing the photovoltaic power generation apparatus 1a in which the regular octagonal shape OCT is obtained by virtually combining a plurality of first photovoltaic power generation elements 10 (the isosceles triangle 11 and the isosceles triangle 12) each having a surface in the shape of a triangle and a plurality of second photovoltaic power generation elements 20 (the isosceles trapezoid 21 and the isosceles trapezoid 22) each having a surface in the shape of a trapezoid, which is a polygon not having less sides than a quadrangle, wherein the first photovoltaic power generation elements 10 (the isosceles triangle 11 and the isosceles triangle 12) and the second photovoltaic power generation elements 20 (the isosceles trapezoid 21 and the isosceles trapezoid 22) are formed by dividing the wafer in the circular shape CCL based on the regular octagonal shape OCT inscribed in the circular shape CCL.

Thus, according to the method (the production method 2) for producing the photovoltaic power generation apparatus 1a, the first photovoltaic power generation elements 10 (the isosceles triangle 11 and the isosceles triangle 12) and the second photovoltaic power generation elements 20 (the isosceles trapezoid 21 and the isosceles trapezoid 22) are formed by dividing the wafer in the circular shape CCL (circular wafer) based on the regular octagonal shape OCT inscribed in the circumference of the circular shape CCL (circular wafer). Thus, a photovoltaic power generation apparatus 1a in which the yield is improved by suppressing the area of the waste regions SC between the circumference (the circular shape CCL) and the regular octagonal shape OCT, and the laying ratio is high can be precisely and easily produced.

According to the method 2 for producing the photovoltaic power generation apparatus 1a, the photovoltaic power generation elements (the first photovoltaic power generation elements 10 and the second photovoltaic power generation elements 20) are produced from the circular wafer (the circular shape CCL). Accordingly, since the first photovoltaic power generation elements 10 and the second photovoltaic power generation elements 20 are formed in the circular wafer (the circular shape CCL), the handling on the edge portion of the wafer is easier than in the case where the photovoltaic power generation elements (the first photovoltaic power generation elements 10 and the second photovoltaic power generation elements 20) are formed in the wafer in the regular octagonal shape OCT. For example, the region corresponding to the waste regions SC can be used as a handling position of the wafer.

When the regular octagonal shape OCT inscribed in the circular wafer (the circular shape CCL) is set (assumed) and the division line DL that links two vertices among eight vertices and divides the regular octagonal shape OCT in half is, for example, perpendicularly set and taken as a perpendicular line, the regular octagonal shape OCT is divided into bilaterally symmetrical pentagons (a pentagon configured by the isosceles triangle 11 and the isosceles trapezoid 21 and a pentagon configured by the isosceles triangle 12 and the isosceles trapezoid 22), and the pentagons are further divided into the first photovoltaic power generation elements 10 and the second photovoltaic power generation elements 20.

Note that the regular octagonal shape OCT is divided by cutting out the regular octagonal shape OCT from the circular shape CCL and further dividing the cut-out regular octagonal shape OCT. According to another method, the regular octagonal shape OCT is divided by dividing the circular shape CCL in a state where the waste regions SC are left to include the regular octagonal shape OCT, and then removing the waste regions SC positioned on the outer side of the regular octagonal shape OCT. In both cases, the wafer in the circular shape CCL is divided based on the regular octagonal shape OCT inscribed in the circular shape CCL. At the time of the division, dividing position indicator marks may be formed as appropriate corresponding to the regular octagonal shape OCT on the surface of the circular wafer.

In the photovoltaic power generation apparatus 1a according to this embodiment, the photovoltaic power generation elements each having a surface in a shape different from a rectangle (the first photovoltaic power generation elements 10 each having a surface in the shape of a triangle and the second photovoltaic power generation elements 20 each having a surface in the shape of a trapezoid) are combined and arranged in an array such that the outer periphery is in the shape of a rectangle, and an arranged state in which no gap is interposed inside the rectangle is achieved, and, therefore, a high filling factor can be maintained.

Hereinafter, the area of the circular wafer (the circular shape CCL) and the area of the regular octagonal shape OCT obtained from the circular wafer will be specifically compared, and the effect of reducing the waste regions SC with respect to the circular wafer will be described below.

When the radius of the circle is taken as r, the area Sc of the circular wafer is obtained as: Sc=π·r². Meanwhile, the area St of the regular octagonal shape OCT is obtained as: St=(½)×{r²×)(sin 45°)}×8=(2√2)×r². Accordingly, the ratio between there areas is obtained as: St/Sc=(2√2)/π=0.90 (90%).

That is to say, the ratio of the waste regions SC with respect to the circular wafer (the circular shape CCL) is suppressed to about 10%, and, since the photovoltaic power generation apparatus 1a is in the shape of a rectangle, 90% (the area of the regular octagonal shape OCT) of the area of the circular wafer can be effectively used as it is in 100%.

Accordingly, in comparison with the conventional example 1 where the solar cell 101 is used only in a ratio of about 76% of the area of the circular wafer (the circular shape CCL), the yield can be improved by 14%, and the resources can be significantly saved.

Furthermore, it is preferable that the first photovoltaic power generation elements 10 and the second photovoltaic power generation elements 20 according to this embodiment are specifically formed as, for example, solar cells (silicon single crystal solar cells).

### Embodiment 2

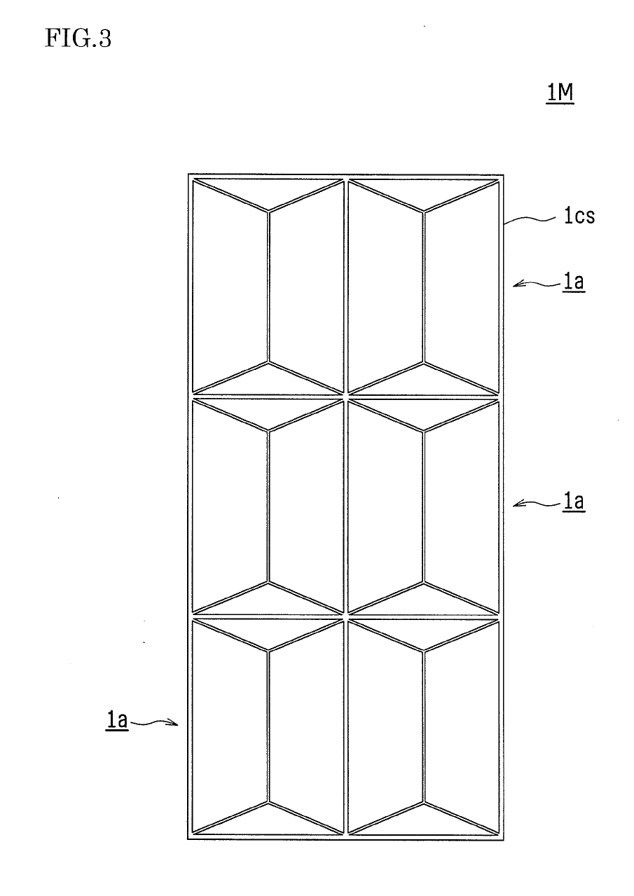

Hereinafter, a photovoltaic power generation apparatus array 1M according to this embodiment will be described with reference to FIG. 3.

FIG. 3 is a schematic plan view showing a planar schematic configuration of the photovoltaic power generation apparatus array 1M according to Embodiment 2 of the present invention.

The photovoltaic power generation apparatus array 1M according to this embodiment is formed by coupling a plurality of photovoltaic power generation apparatuses 1a according to Embodiment 1. That is to say, 2 rows×3 columns of the photovoltaic power generation apparatuses 1a, i.e., six photovoltaic power generation apparatuses 1a are arranged in total. The six photovoltaic power generation apparatuses 1a may be connected to each other in various forms such as 6-series connection, 6-parallel connection, and 2-series-3-parallel connection. Accordingly, a photovoltaic power generation apparatus array 1M having output characteristics according to required specifications is obtained.

The photovoltaic power generation apparatus array 1M according to this embodiment is the photovoltaic power generation apparatus array 1M in which a plurality of photovoltaic power generation apparatuses 1a are connected in an array, where the photovoltaic power generation apparatuses la are the photovoltaic power generation apparatuses 1a described in Embodiment 1.

Accordingly, in the photovoltaic power generation apparatus array 1M, since a plurality of photovoltaic power generation apparatuses 1a each in the shape of a rectangle are connected in an array, the laying ratio is high, and high-capacity photovoltaic power generation with good yield can be easily achieved.

The six photovoltaic power generation apparatuses 1a may be connected (coupled) to each other, for example, using a wiring board 1cs. The wiring board 1cs may be configured by a single wiring board, or may be a plurality of coupled wiring boards, with respect to the photovoltaic power generation apparatus array 1M.

The photovoltaic power generation apparatus array 1M is formed by coupling a plurality of photovoltaic power generation apparatuses 1a in which all of the first photovoltaic power generation elements 10 and the second photovoltaic power generation elements 20 formed from the circular shape CCL are used. That is to say, although the first photovoltaic power generation elements 10 and the second photovoltaic power generation elements 20 having shapes totally different from each other are formed from the wafer in the circular shape CCL (the wafer in the regular octagonal shape OCT), there is no waste element, and, therefore, the production consistency is fully achieved, and extremely high productivity can be achieved.

### Embodiment 3

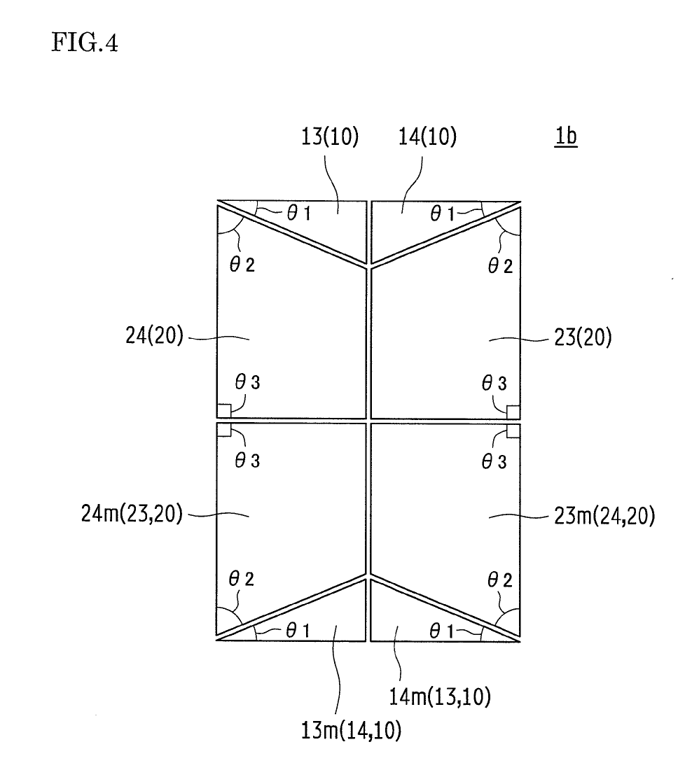

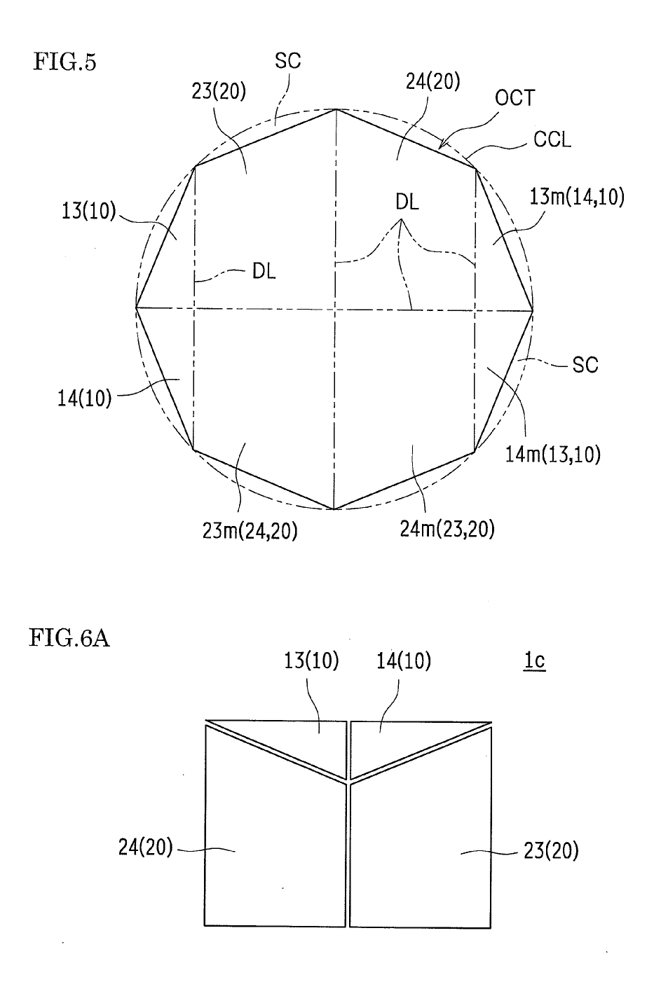

Hereinafter, a photovoltaic power generation apparatus 1b, a method for producing the photovoltaic power generation apparatus 1b, and a wafer used to produce the photovoltaic power generation apparatus 1b according to this embodiment will be described with reference to FIGS. 4 and 5. A basic configuration of the photovoltaic power generation apparatus 1b is similar to that of the photovoltaic power generation apparatus 1a according to Embodiment 1, and, therefore, the same reference numerals are used as appropriate, and different matters will be mainly described.

The first photovoltaic power generation elements 10 and the second photovoltaic power generation elements 20 used in the photovoltaic power generation apparatus 1b are respectively formed by symmetrically dividing the first photovoltaic power generation elements 10 and the second photovoltaic power generation elements 20 according to Embodiment 1 in half, and the number of elements (the number of first photovoltaic power generation elements 10 and the number of second photovoltaic power generation elements 20) are twice that in the photovoltaic power generation apparatus la. Furthermore, in the photovoltaic power generation apparatus 1b, all of the first photovoltaic power generation elements 10 and the second photovoltaic power generation elements 20 cut out from the wafer in the circular shape CCL (the regular octagonal shape OCT) are arranged (see FIG. 5).

FIG. 4 is a schematic plan view showing a planar schematic configuration of the photovoltaic power generation apparatus 1b according to Embodiment 3 of the present invention.

The photovoltaic power generation apparatus 1b according to this embodiment includes the first photovoltaic power generation elements 10 (a right-angled triangle 13, a right-angled triangle 14, a symmetrical triangle 13m, and a symmetrical triangle 14m) each having a surface in the shape of a triangle, and the second photovoltaic power generation elements 20 (a right-angled trapezoid 23, a right-angled trapezoid 24, a symmetrical trapezoid 23m, and a symmetrical trapezoid 24m) each having a surface in the shape of a trapezoid. Note that a trapezoid (right-angled trapezoid, symmetrical trapezoid) according to this embodiment is a type of a polygon not having less sides than a quadrangle.

Here, the symmetrical triangle 13m is mirror symmetric to the right-angled triangle 13, and has the same shape as the right-angled triangle 14. The symmetrical triangle 14m is mirror symmetric to the right-angled triangle 14, and has the same shape as the right-angled triangle 13. That is to say, the symmetrical triangle 13m has a shape obtained by rotating the right-angled triangle 14 by 180 degrees, and the symmetrical triangle 14m has a shape obtained by rotating the right-angled triangle 13 by 180 degrees.

Furthermore, in the right-angled trapezoid 23, an interior angle θ3 between one leg (shorter leg) and the lower base is a right angle, and, in the right-angled trapezoid 24, an interior angle θ3 between one leg (shorter leg) and the lower base is a right angle. The symmetrical trapezoid 23m is mirror symmetric to the right-angled trapezoid 23, and has the same shape as the right-angled trapezoid 24. The symmetrical trapezoid 24m is mirror symmetric to the right-angled trapezoid 24, and has the same shape as the right-angled trapezoid 23. That is to say, the symmetrical trapezoid 23m has a shape obtained by rotating the right-angled trapezoid 24 by 180 degrees, and the symmetrical trapezoid 24m has a shape obtained by rotating the right-angled trapezoid 23 by 180 degrees.

In the photovoltaic power generation apparatus 1b, the same number of first photovoltaic power generation elements 10 (four elements, namely the right-angled triangle 13, the right-angled triangle 14, the symmetrical triangle 13m, and the symmetrical triangle 14m) and second photovoltaic power generation elements 20 (four elements, namely the right-angled trapezoid 23, the right-angled trapezoid 24, the symmetrical trapezoid 23m, and the symmetrical trapezoid 24m) are combined, forming a rectangle.

The photovoltaic power generation apparatus 1b has an outer periphery that is in the shape of a rectangle, and includes another four rectangles. That is to say, the combination of the right-angled triangle 13 and the right-angled trapezoid 24, the combination of the right-angled triangle 14 and the right-angled trapezoid 23, the combination of the symmetrical triangle 13m and the symmetrical trapezoid 24m, and the combination of the symmetrical triangle 14m and the symmetrical trapezoid 23m respectively form rectangles.

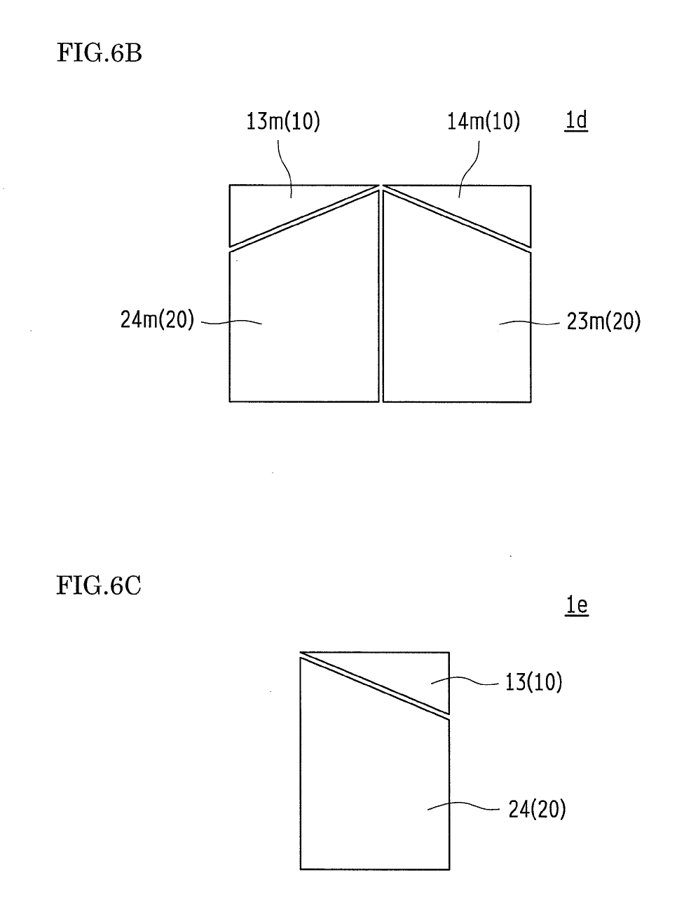

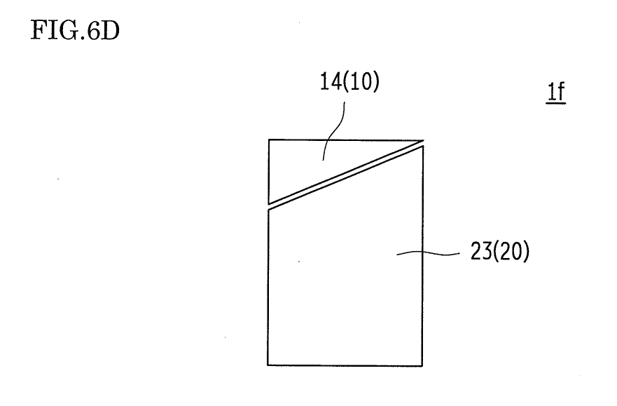

Accordingly, four minimum connection units UN can be formed each by combining one right-angled triangle (any one of the right-angled triangle 13, the right-angled triangle 14, the symmetrical triangle 13m, and the symmetrical triangle 14m) and one right-angled trapezoid (any one of the right-angled trapezoid 23, the right-angled trapezoid 24, the symmetrical trapezoid 23m, and the symmetrical trapezoid 24m) connected in parallel (see FIGS. 1B, 6C, and 6D).

That is to say, in the photovoltaic power generation apparatus 1b, the relationship between the interior angle θ1 in the triangle (the first photovoltaic power generation element 10) and the interior angle θ2 in the trapezoid (the second photovoltaic power generation element 20) is the same as that in Embodiment 1, and, therefore, each rectangle is configured by a combination of the right-angled triangle and the right-angled trapezoid.

As described above, in the photovoltaic power generation apparatus 1b, the triangles (the first photovoltaic power generations elements 10) are right-angled triangles (the right-angled triangle 13, the right-angled triangle 14, the symmetrical triangle 13m, and the symmetrical triangle 14m), and the trapezoids (the second photovoltaic power generation elements 20) are right-angled trapezoids (the right-angled trapezoid 23, the right-angled trapezoid 24, the symmetrical trapezoid 23m, and the symmetrical trapezoid 24m) in which the interior angle θ3 between one leg (shorter leg) and the lower base is a right angle.

Accordingly, since the photovoltaic power generation apparatus 1b is configured by a combination of right-angled triangles (the right-angled triangle 13, the right-angled triangle 14, the symmetrical triangle 13m, and the symmetrical triangle 14m) and right-angled trapezoids (the right-angled trapezoid 23, the right-angled trapezoid 24, the symmetrical trapezoid 23m, and the symmetrical trapezoid 24m) (e.g., the right-angled triangle 13 and the right-angled trapezoid 24, the right-angled triangle 14 and the right-angled trapezoid 23, the symmetrical triangle 13m and the symmetrical trapezoid 24m, and the symmetrical triangle 14m and the symmetrical trapezoid 23m), a rectangle can be configured by a combination of one first photovoltaic power generation element 10 and one second photovoltaic power generation element 20, and, therefore, a highly applicable and more effective laying operation can be performed using a large number of rectangles.

Furthermore, in the photovoltaic power generation apparatus 1b according to this embodiment, the triangles (the first photovoltaic power generation elements 10) include right-angled triangles (the right-angled triangle 13 and the right-angled triangle 14) and symmetrical triangles (the symmetrical triangle 13m and the symmetrical triangle 14m), which are mirror symmetric to the right-angled triangles, and the trapezoids, which are polygons, include right-angled trapezoids (the right-angled trapezoid 23 and the right-angled trapezoid 24) and symmetrical trapezoids (the symmetrical trapezoid 23m and the symmetrical trapezoid 24m), which are mirror symmetric to the right-angled trapezoids.

Accordingly, since the photovoltaic power generation apparatus 1b is configured by a combination of right-angled triangles (the right-angled triangle 13 and the right-angled triangle 14), symmetrical triangles (the symmetrical triangle 13m and the symmetrical triangle 14m), which are mirror symmetric to the right-angled triangles, right-angled trapezoids (the right-angled trapezoid 23 and the right-angled trapezoid 24), and symmetrical trapezoids (the symmetrical trapezoid 23m and the symmetrical trapezoid 24m), which are mirror symmetric to the right-angled trapezoids, the photovoltaic power generation apparatus 1b includes a rectangle configured by right-angled triangles (the right-angled triangle 13 and the right-angled triangle 14) and right-angled trapezoids (the right-angled trapezoid 23 and the right-angled trapezoid 24) and a rectangle configured by symmetrical triangles (the symmetrical triangle 13m and the symmetrical triangle 14m) and symmetrical trapezoids (the symmetrical trapezoid 23m and the symmetrical trapezoid 24m). Thus, the symmetric properties in arrangement of the first photovoltaic power generation elements 10 and the second photovoltaic power generation elements 20 can be improved, and the unevenness in the output characteristics can be alleviated.

Note that, in the photovoltaic power generation apparatus 1b, four minimum connection units UN are arranged, and, therefore, the number of units connected in series can be increased. When all four unites are arranged in series, the voltage can be increased to four times the voltage generated by the minimum connection unit UN. That is to say, output characteristics suitable for high-voltage (low-current) applications can be obtained.

The arrangement in the lower portion (the symmetrical triangle 13m, the symmetrical triangle 14m, the symmetrical trapezoid 23m, and the symmetrical trapezoid 24m) shown in FIG. 4 may be horizontally reversed with respect to the arrangement in the upper portion (the right-angled triangle 13, the right-angled triangle 14, the right-angled trapezoid 23, and the right-angled trapezoid 24). Furthermore, the arrangement in the upper portion may be horizontally reversed with respect to the arrangement in the lower portion.

FIG. 5 is an explanatory view illustrating a state in which the first photovoltaic power generation elements 10 and the second photovoltaic power generation elements 20 forming the photovoltaic power generation apparatus 1b shown in FIG. 4 are obtained by dividing the circular shape CCL along the division lines DL.

A basic configuration in this embodiment is as described in FIG. 2 in Embodiment 1. In this embodiment, the triangles and the trapezoids in Embodiment 1 are further divided symmetrically in half, and, therefore, the number of first photovoltaic power generation elements 10 and the number of second photovoltaic power generation elements 20 are twice those in Embodiment 1.

Specifically, the isosceles triangle 11 in Embodiment 1 is divided in half along the division line DL that links the center of the bottom side and the vertex, forming the right-angled triangle 13 and the right-angled triangle 14, and the isosceles triangle 12 in Embodiment 1 is divided in half in a similar manner, forming the symmetrical triangle 13m and the symmetrical triangle 14m. Furthermore, the isosceles trapezoid 21 in Embodiment 1 is divided in half along the division line DL that passes through the center of the lower base and the center of the upper base, forming the right-angled trapezoid 23 and the symmetrical trapezoid 23m, and the isosceles trapezoid 22 in Embodiment 1 is divided in half in a similar manner, forming the right-angled trapezoid 24 and the symmetrical trapezoid 24m.

Note that the ratio of the waste regions SC with respect to the circular wafer (the circular shape CCL) and the yield of the photovoltaic power generation apparatus 1b from circular wafer are similar to those in Embodiment 1. Furthermore, since a larger number (twice the number in the photovoltaic power generation apparatus la) of first photovoltaic power generation elements 10 and second photovoltaic power generation elements 20 forming a small rectangles are cut out, the number of elements connected in series can be increased.

Furthermore, in the photovoltaic power generation apparatus 1b according to this embodiment, the wafer in the regular octagonal shape OCT can be used as the wafer as in the photovoltaic power generation apparatus 1a according to Embodiment 1.

That is to say, the wafer according to this embodiment has a surface in the regular octagonal shape OCT cut out from the circular shape CCL. Accordingly, since the wafer according to this embodiment has been cut out from the circular shape CCL as a wafer in the regular octagonal shape OCT, the waste regions SC (the waste regions SC between the circumference of the circular shape CCL and the regular octagonal shape OCT) of the wafer have been removed in advance, and the combination of the first photovoltaic power generation elements 10 (the right-angled triangle 13, the right-angled triangle 14, the symmetrical triangle 13m, and the symmetrical triangle 14m) each in the shape of a triangle and the second photovoltaic power generation elements 20 (the right-angled trapezoid 23, the right-angled trapezoid 24, the symmetrical trapezoid 23m, and the symmetrical trapezoid 24m) each in the shape of a trapezoid can be easily and precisely cut out. Thus, a photovoltaic power generation apparatus 1b in which the yield from the wafer and the laying ratio on the installation face are improved can be produced at a high productivity.

Note that the method for producing the photovoltaic power generation apparatus 1b is basically the same as the production method in Embodiment 1, and is different therefrom in that the first photovoltaic power generation elements 10 and the second photovoltaic power generation elements 20 are further divided symmetrically in half. That is to say, the elements in this embodiment are formed by vertically symmetrically dividing the regular octagonal shape OCT shown in Embodiment 1 (FIG. 2). The order in which the first photovoltaic power generation elements 10 and the second photovoltaic power generation elements 20 are symmetrically divided in half can be freely selected.

### Embodiment 4

Hereinafter, a photovoltaic power generation apparatus 1c to a photovoltaic power generation apparatus if according to this embodiment will be described with reference to FIGS. 6A to 6D. Note that the photovoltaic power generation apparatus 1c to the photovoltaic power generation apparatus if according to this embodiment are obtained by extracting rectangles included in the photovoltaic power generation apparatus 1b according to Embodiment 3. A basic configuration thereof is similar to that of the photovoltaic power generation apparatus 1a according to Embodiment 1 or the photovoltaic power generation apparatus 1b according to Embodiment 3, and, therefore, the same reference numerals are used as appropriate, and different matters will be mainly described.

FIG. 6A is a schematic plan view showing a planar schematic configuration of the photovoltaic power generation apparatus 1c according to Embodiment 4 of the present invention.

The photovoltaic power generation apparatus 1c according to this embodiment includes a rectangle (the minimum connection unit UN) configured by the right-angled triangle 13 and the right-angled trapezoid 24 and a rectangle (the minimum connection unit UN) configured by the right-angled triangle 14 and the right-angled trapezoid 23. That is to say, a half of the photovoltaic power generation apparatus 1b (four elements in the upper portion in FIG. 4) is included.

This apparatus can be configured as a simple module (small module) in which these two rectangles (the minimum connection units UN) are connected in series or in parallel. In this example, although the elements in the upper portion of the photovoltaic power generation apparatus 1b are extracted and horizontally arranged, they may be vertically arranged if necessary.

FIG. 6B is a schematic plan view showing a planar schematic configuration of a photovoltaic power generation apparatus 1d according to Embodiment 4 of the present invention.

The photovoltaic power generation apparatus 1d according to this embodiment includes a rectangle (the minimum connection unit UN) configured by the symmetrical triangle 13m and the symmetrical trapezoid 24m and a rectangle (the minimum connection unit UN) configured by the symmetrical triangle 14m and the symmetrical trapezoid 23m. That is to say, a half of the photovoltaic power generation apparatus 1b (four elements in the lower portion in FIG. 4) is included. The photovoltaic power generation apparatus 1d and the photovoltaic power generation apparatus 1c are in mutually different planner arrangements but can have the same output characteristics.

This apparatus can be configured as a simple module in which these two rectangles (the minimum connection units UN) are connected in series or in parallel. In this example, although the elements in the lower portion of the photovoltaic power generation apparatus 1b are extracted and horizontally arranged, they may be vertically arranged if necessary.

FIG. 6C is a schematic plan view showing a planar schematic configuration of the photovoltaic power generation apparatus 1e according to Embodiment 4 of the present invention.

The photovoltaic power generation apparatus 1e according to this embodiment includes a rectangle (the minimum connection unit UN) configured by the right-angled triangle 13 and the right-angled trapezoid 24. That is to say, the left half of the photovoltaic power generation apparatus 1c (FIG. 6A) is included.

FIG. 6D is a schematic plan view showing a planar schematic configuration of the photovoltaic power generation apparatus if according to Embodiment 4 of the present invention.

The photovoltaic power generation apparatus if according to this embodiment includes a rectangle (the minimum connection unit UN) configured by the right-angled triangle 14 and the right-angled trapezoid 23. That is to say, the right half of the photovoltaic power generation apparatus 1c (FIG. 6A) is included.

As shown in FIGS. 6A to 6D, photovoltaic power generation apparatuses (the photovoltaic power generation apparatus 1c to the photovoltaic power generation apparatus 1f) in various planner arrangements can be provided based on the minimum connection unit UN. Accordingly, the photovoltaic power generation apparatus 1c to the photovoltaic power generation apparatus if according to this embodiment have small elements and outer shapes, and have rectangular outer shapes (outer peripheries), and, therefore, a highly applicable basic photovoltaic power generation apparatus (basic module) in which elements can be freely laid is obtained, and can be used in various applications.

### Embodiment 5

In Embodiments 1 to 4, a trapezoid (isosceles trapezoid, right-angled trapezoid) was given as an example of a polygon not having less sides than a quadrangle (polygon the number of whose sides is not less than 4), but, in this embodiment, a hexagon and a pentagon will be described as other examples of a polygon not having less sides than a quadrangle.

Furthermore, in Embodiments 1 to 4, a combination of one first photovoltaic power generation element 10 in the shape of a triangle and one second photovoltaic power generation element 20 in the shape of a polygon was described, but, in this embodiment, a case will be described in which the photovoltaic power generation elements are combined such that the number of elements of one of the types is an integer multiple of the number of elements of the other type.

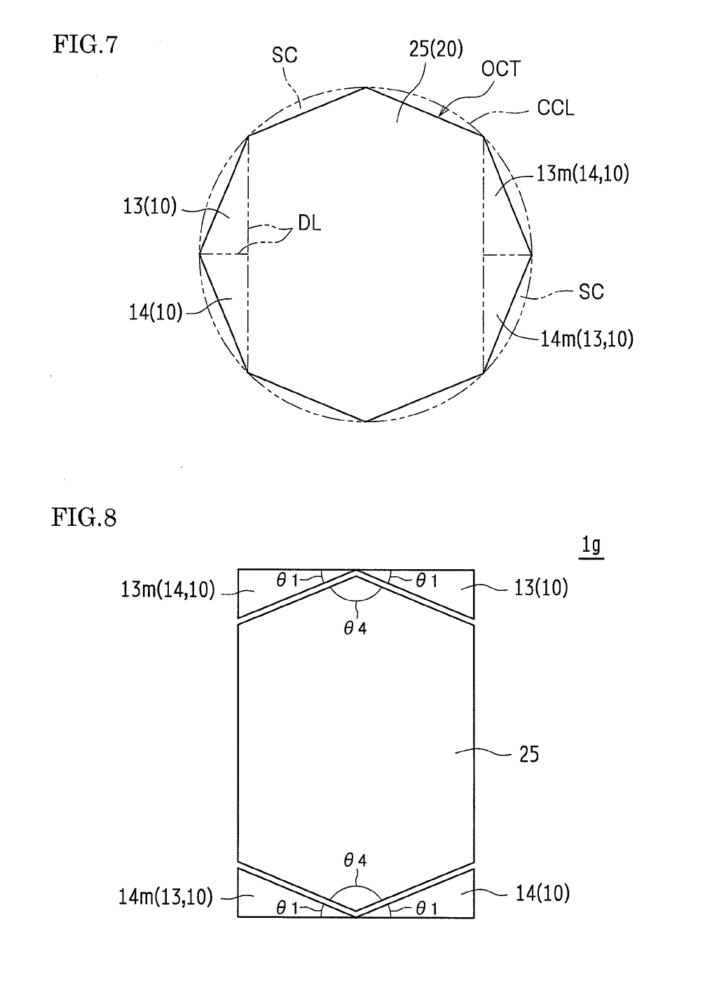

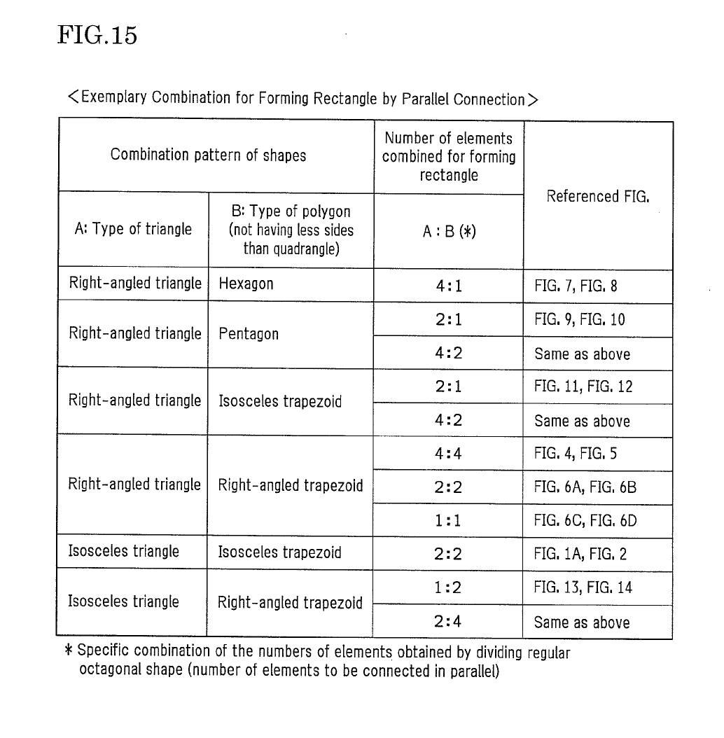

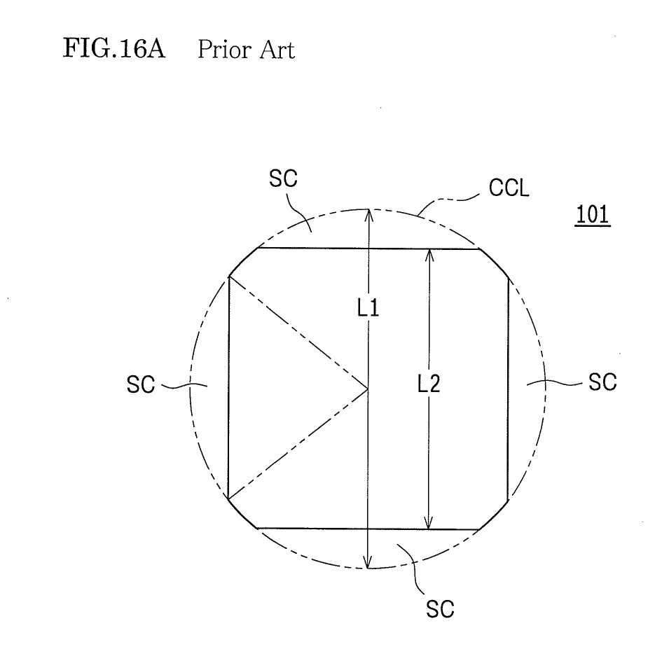

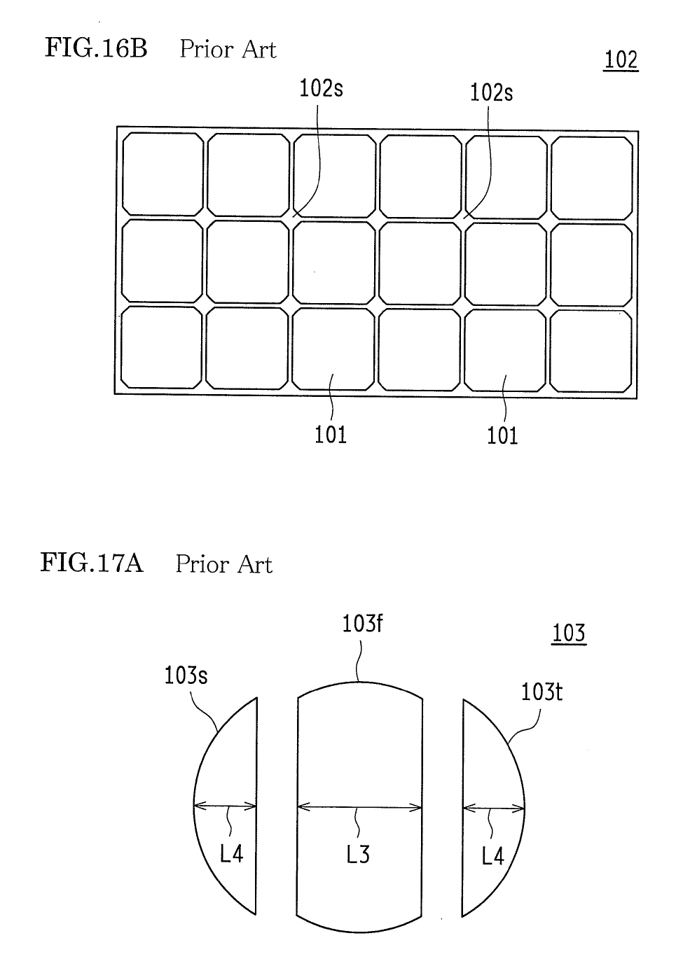

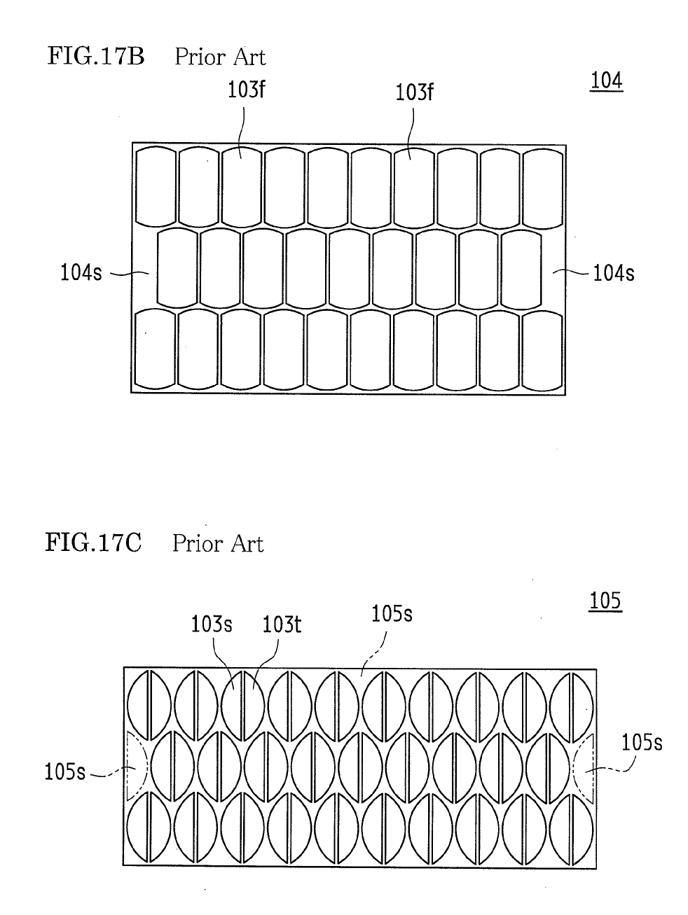

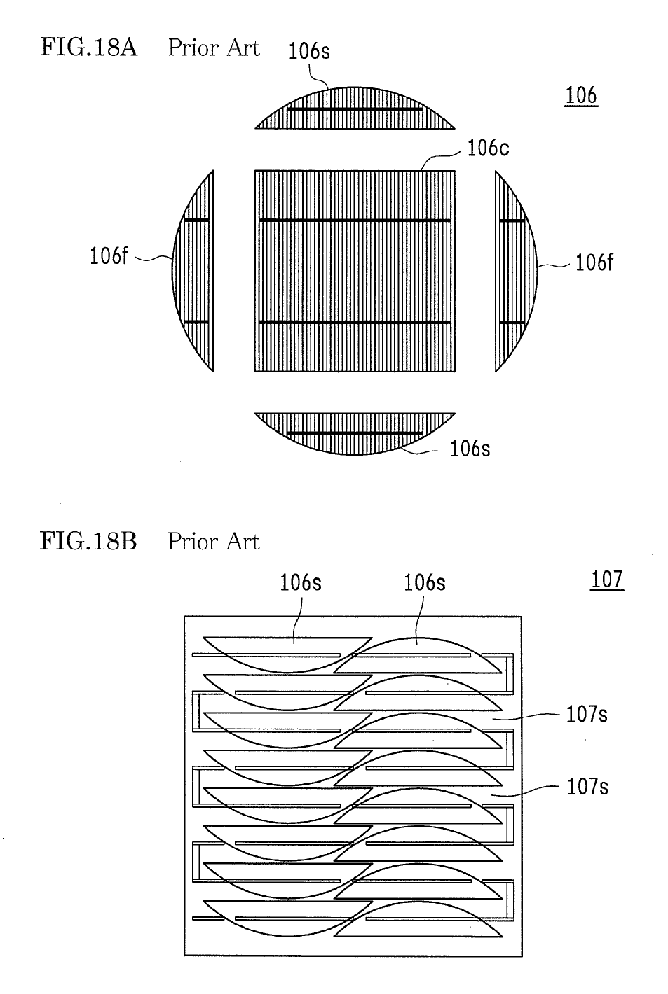

Hereinafter, a photovoltaic power generation apparatus 1g (FIG. 8), a photovoltaic power generation apparatus 1h (FIG. 10), a photovoltaic power generation apparatus 11 (FIG. 12), and a photovoltaic power generation apparatus 1j (FIG. 14) according to this embodiment will be described with reference to FIGS. 7 to 14. Basic configurations of the photovoltaic power generation apparatus 1g, the photovoltaic power generation apparatus 1h, the photovoltaic power generation apparatus 1i, and the photovoltaic power generation apparatus 1j are similar to those of the photovoltaic power generation apparatus 1a to the photovoltaic power generation apparatus if according to Embodiments 1 to 4, and, therefore, the same reference numerals are used as appropriate, and different matters will be mainly described. In the following description, the photovoltaic power generation apparatus 1a to the photovoltaic power generation apparatus 1j may be simply referred to as a photovoltaic power generation apparatus 1 if they do not have to be particularly specified.

In this embodiment, a case will be described in which the photovoltaic power generation apparatus 1g, the photovoltaic power generation apparatus 1h, the photovoltaic power generation apparatus 1i, and the photovoltaic power generation apparatus 1j are obtained by dividing the circular shape CCL along the division lines DL, but they may be obtained by dividing the regular octagonal shape OCT along the division lines DL.

Furthermore, in this embodiment, a state in which the circular shape CCL is divided is shown in a preceding drawing, and a photovoltaic power generation apparatus such as the photovoltaic power generation apparatus 1g configured by a combination of the first photovoltaic power generation elements 10 and the second photovoltaic power generation element 20 obtained by that division is shown in a following drawing.

FIG. 7 is an explanatory view illustrating a state in which the first photovoltaic power generation elements 10 and the second photovoltaic power generation element 20 forming the photovoltaic power generation apparatus 1g according to Embodiment 5 of the present invention are obtained by dividing the circular shape CCL along the division lines DL.

FIG. 8 is a schematic plan view showing a planar schematic configuration of the photovoltaic power generation apparatus 1g configured by a combination of the first photovoltaic power generation elements 10 and the second photovoltaic power generation element 20 obtained by the division shown in FIG. 7.

In FIG. 7, four first photovoltaic power generation elements 10 (the right-angled triangle 13, the right-angled triangle 14, the symmetrical triangle 13m, and the symmetrical triangle 14m) each having a surface in the shape of a triangle and one second photovoltaic power generation element 20 having a surface in the shape of a hexagon 25, which is a polygon not having less sides than a quadrangle, are formed by dividing the circular wafer (the circular shape CCL) along the division lines DL. Note that a hexagon according to this embodiment is a type of a polygon not having less sides than a quadrangle.

Furthermore, interior angles θ4 formed by the inclined sides of the hexagon 25 are each (¾)π radians, and one of the interior angles θ4 of the hexagon 25 is disposed adjacent to the interior angle θ1 ((⅛)π radians) of the right-angled triangle 13 and the interior angle θ1 of the symmetrical triangle 13m, and the other interior angle θ4 of the hexagon 25 is disposed adjacent to the interior angle θ1 of the right-angled triangle 14 and the interior angle θ1 of the symmetrical triangle 14m, forming a rectangle (the photovoltaic power generation apparatus 1g).

That is to say, in the photovoltaic power generation apparatus 1g, four right-angled triangles are arranged with respect to one hexagon 25, that is, the photovoltaic power generation elements are combined such that the number (four) of elements of one of the types (the first photovoltaic power generation elements 10 each in the shape of a right-angled triangle) is an integer multiple (four times in this example) of the number (one) of elements of the other type (the second photovoltaic power generation elements 20 each in the shape of a hexagon), forming a rectangle.

Furthermore, in the photovoltaic power generation apparatus 1g, four first photovoltaic power generation elements 10 are connected in parallel to one second photovoltaic power generation element 20. That is to say, the photovoltaic power generation elements are connected in parallel such that the number of elements of one of the types (the first photovoltaic power generation elements 10) is an integer multiple of the number of elements of the other type (the second photovoltaic power generation elements 20).

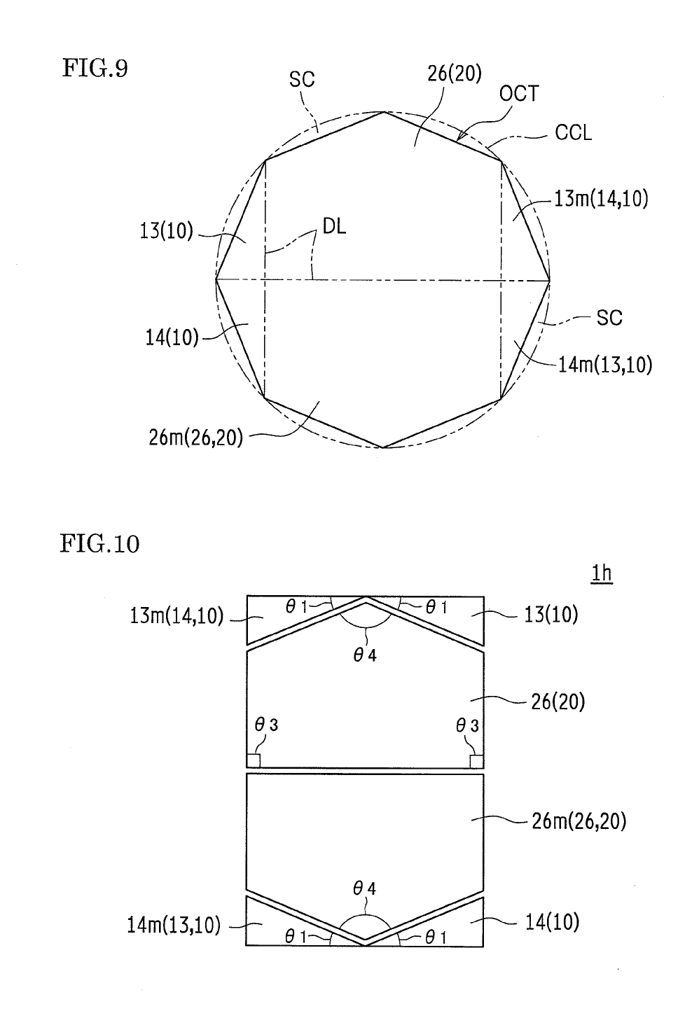

FIG. 9 is an explanatory view illustrating a state in which the first photovoltaic power generation elements 10 and the second photovoltaic power generation elements 20 forming the photovoltaic power generation apparatus 1h according to Embodiment 5 of the present invention are obtained by dividing the circular shape CCL along the division lines DL.

FIG. 10 is a schematic plan view showing a planar schematic configuration of the photovoltaic power generation apparatus 1h configured by a combination of the first photovoltaic power generation elements 10 and the second photovoltaic power generation elements 20 obtained by the division shown in FIG. 9.

In FIG. 9, four first photovoltaic power generation elements 10 (the right-angled triangle 13, the right-angled triangle 14, the symmetrical triangle 13m, and the symmetrical triangle 14m) each having a surface in the shape of a triangle and two second photovoltaic power generation elements 20 having a surface in the shape of a pentagon 26 and a symmetrical pentagon 26m (which is also a pentagon 26), which are each a polygon not having less sides than a quadrangle, are formed by dividing the circular wafer (the circular shape CCL) along the division lines DL. Note that a pentagon according to this embodiment is a type of a polygon not having less sides than a quadrangle. Furthermore, interior angles θ3 formed by two parallel sides of and the side therebetween in the pentagons 26 are each a right angle.

Furthermore, an interior angle θ4 formed by the inclined sides of the pentagon 26 is (¾)π radians, and the interior angle θ4 of the pentagon 26 is disposed adjacent to the interior angle θ1 ((⅛)π radians) of the right-angled triangle 13 and the interior angle θ1 of the symmetrical triangle 13m, forming a rectangle. Furthermore, an interior angle θ4 formed by the inclined sides of the symmetrical pentagon 26m is (¾)π radians, and the interior angle θ4 of the symmetrical pentagon 26m is disposed adjacent to the interior angle θ1 ((⅛)π radians) of the right-angled triangle 14 and the interior angle θ1 of the symmetrical triangle 14m, forming a rectangle. Accordingly, the photovoltaic power generation apparatus 1h includes a rectangle configured by a combination of the pentagon 26 with the right-angled triangle 13 and the symmetrical triangle 13m and a rectangle configured by a combination of the symmetrical pentagon 26m with the right-angled triangle 14 and the symmetrical triangle 14m.

That is to say, in the photovoltaic power generation apparatus 1h, two right-angled triangles (the right-angled triangle 13 and the symmetrical triangle 13m) are arranged with respect to one pentagon 26, and, furthermore, two right-angled triangles (the right-angled triangle 14 and the symmetrical triangle 14m) are arranged with respect to one symmetrical pentagon 26m.

That is to say, the photovoltaic power generation elements are combined such that the number (two or four) of elements of one of the types (the first photovoltaic power generation elements 10 each in the shape of a right-angled triangle) is an integer multiple (twice in this example) of the number (one or two) of elements of the other type (the second photovoltaic power generation elements 20 each in the shape of a pentagon), forming a rectangle.

In the photovoltaic power generation apparatus 1h, two first photovoltaic power generation elements 10 are connected in parallel to one second photovoltaic power generation element 20. Furthermore, four first photovoltaic power generation elements 10 are connected in parallel to two second photovoltaic power generation elements 20. That is to say, the photovoltaic power generation elements are connected in parallel such that the number of elements of one of the types (the first photovoltaic power generation elements 10) is an integer multiple of the number of elements of the other type (the second photovoltaic power generation elements 20).

The rectangles (the set of the pentagons 26, the right-angled triangle 13, and the symmetrical triangle 13m, and the set of the symmetrical pentagon 26m, the right-angled triangle 14, and the symmetrical triangle 14m) may be connected to each other in series.

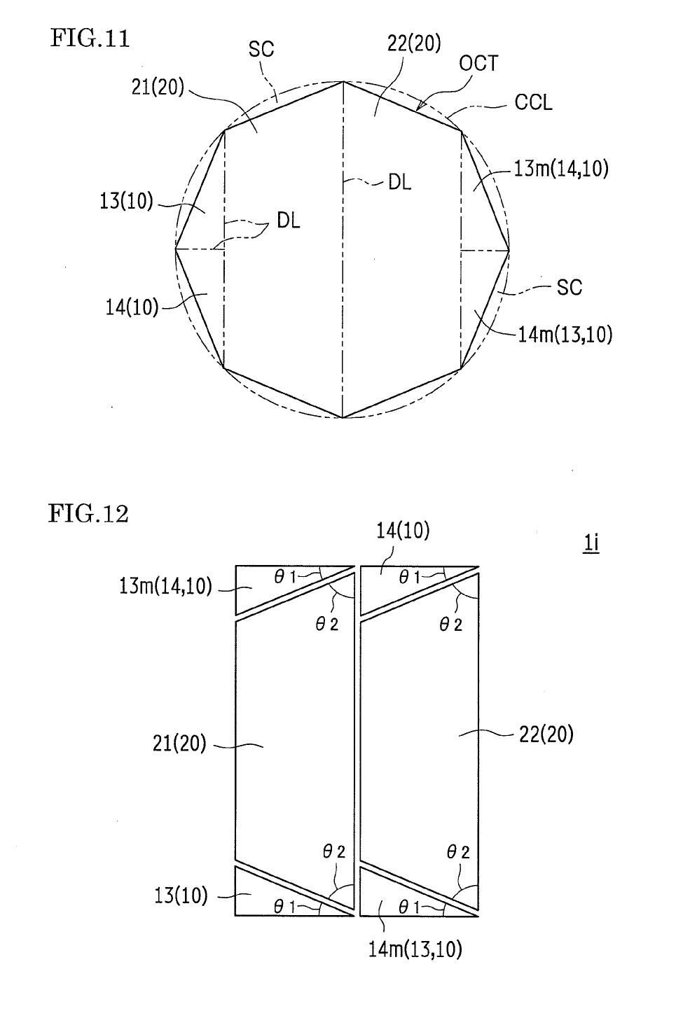

FIG. 11 is an explanatory view illustrating a state in which the first photovoltaic power generation elements 10 and the second photovoltaic power generation elements 20 forming the photovoltaic power generation apparatus 1i according to Embodiment 5 of the present invention are obtained by dividing the circular shape CCL along the division lines DL.

FIG. 12 is a schematic plan view showing a planar schematic configuration of the photovoltaic power generation apparatus 11 configured by a combination of the first photovoltaic power generation elements 10 and the second photovoltaic power generation elements 20 obtained by the division shown in FIG. 11.

In FIG. 11, four first photovoltaic power generation elements 10 (the right-angled triangle 13, the right-angled triangle 14, the symmetrical triangle 13m, and the symmetrical triangle 14m) each having a surface in the shape of a triangle and two second photovoltaic power generation elements 20 (the isosceles trapezoid 21 and the isosceles trapezoid 22) each having a surface in the shape of a trapezoid, which is a polygon not having less sides than a quadrangle, are formed by dividing the circular wafer (the circular shape CCL) along the division lines DL. Note that a trapezoid (isosceles trapezoid) according to this embodiment is a type of a polygon not having less sides than a quadrangle.

Furthermore, interior angles θ2 formed by the legs and the lower base of the isosceles trapezoid 21 are each (⅜)π radians, and the interior angles θ2 of the isosceles trapezoid 21 are arranged adjacent to the interior angle θ1 ((⅛)π radians) of the right-angled triangle 13 and the interior angle θ1 of the symmetrical triangle 13m, forming a rectangle. Furthermore, the interior angles θ2 of the isosceles trapezoid 22 are arranged adjacent to the interior angle θ1 of the right-angled triangle 14 and the interior angle θ1 of the symmetrical triangle 14m, forming a rectangle.

Accordingly, the photovoltaic power generation apparatus 1i includes a rectangle configured by a combination of the isosceles trapezoid 21 with the right-angled triangle 13 and the symmetrical triangle 13m and a rectangle configured by a combination of the isosceles trapezoid 22 with the right-angled triangle 14 and the symmetrical triangle 14m.

That is to say, in the photovoltaic power generation apparatus 1i, two right-angled triangles (the right-angled triangle 13 and the symmetrical triangle 13m) are arranged with respect to one trapezoid (the isosceles trapezoid 21), and, furthermore, two right-angled triangles (the right-angled triangle 14 and the symmetrical triangle 14m) are arranged with respect to one trapezoid (the isosceles trapezoid 22). Thus, the triangles are right-angled triangles (the right-angled triangle 13, the symmetrical triangle 13m, the right-angled triangle 14, and the symmetrical triangle 14m), and the polygons are trapezoids (the isosceles trapezoid 21 for the right-angled triangle 13 and the symmetrical triangle 13m, and the isosceles trapezoid 22 for the right-angled triangle 14 and the symmetrical triangle 14m).

That is to say, the photovoltaic power generation elements are combined such that the number (two or four) of elements of one of the types (the first photovoltaic power generation elements 10 each in the shape of a right-angled triangle) is an integer multiple (twice in this example) of the number (one or two) of elements of the other type (the second photovoltaic power generation elements 20 each in the shape of a trapezoid (isosceles trapezoid)), forming a rectangle.

In the photovoltaic power generation apparatus 1i, two first photovoltaic power generation elements 10 are connected in parallel to one second photovoltaic power generation element 20. Furthermore, four first photovoltaic power generation elements 10 are connected in parallel to two second photovoltaic power generation elements 20. That is to say, the photovoltaic power generation elements are connected in parallel such that the number of elements of one of the types (the first photovoltaic power generation elements 10) is an integer multiple of the number of elements of the other type (the second photovoltaic power generation elements 20).

The rectangles (the set of the isosceles trapezoid 21, the right-angled triangle 13, and the symmetrical triangle 13m, and the set of the isosceles trapezoid 22, the right-angled triangle 14, and the symmetrical triangle 14m) may be connected to each other in series.

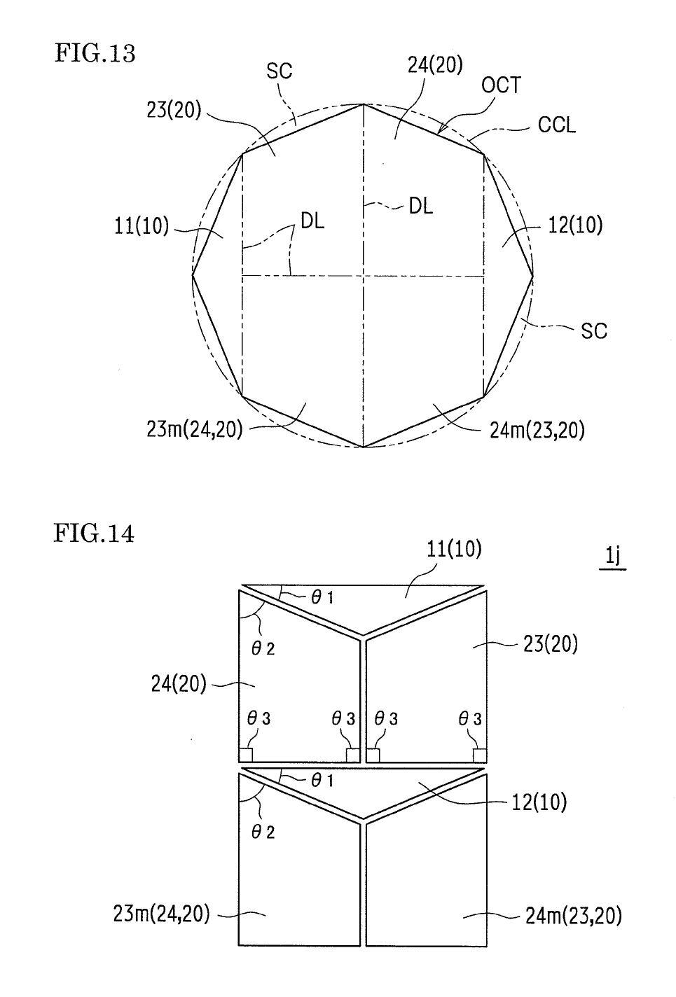

FIG. 13 is an explanatory view illustrating a state in which the first photovoltaic power generation elements 10 and the second photovoltaic power generation elements 20 forming the photovoltaic power generation apparatus 1j according to Embodiment 5 of the present invention are obtained by dividing the circular shape CCL along the division lines DL.

FIG. 14 is a schematic plan view showing a planar schematic configuration of the photovoltaic power generation apparatus 1j configured by a combination of the first photovoltaic power generation elements 10 and the second photovoltaic power generation elements 20 obtained by the division shown in FIG. 13.

In FIG. 13, two first photovoltaic power generation elements 10 (the isosceles triangle 11 and the isosceles triangle 12) each having a surface in the shape of a triangle and four second photovoltaic power generation elements 20 (the right-angled trapezoid 23, the symmetrical trapezoid 23m, the right-angled trapezoid 24, and the symmetrical trapezoid 24m) each having a surface in the shape of a right-angled trapezoid, which is a polygon not having less sides than a quadrangle, are formed by dividing the circular wafer (the circular shape CCL) along the division lines DL. Note that a right-angled trapezoid according to this embodiment is a type of a polygon not having less sides than a quadrangle.

Furthermore, interior angles θ2 of the right-angled trapezoid 23, the symmetrical trapezoid 23m, the right-angled trapezoid 24, and the symmetrical trapezoid 24m are each (⅜)π radians, and the interior angles θ2 of the right-angled trapezoid 23 and the right-angled trapezoid 24 are arranged adjacent to the interior angles θ1 ((⅛)π radians) of the isosceles triangle 11, forming a rectangle. Furthermore, the interior angles θ2 of the symmetrical trapezoid 23m and the symmetrical trapezoid 24m are arranged adjacent to the interior angles θ1 ((⅛)π radians) of the isosceles triangle 12, forming a rectangle.

Accordingly, the photovoltaic power generation apparatus 1j includes a rectangle configured by a combination of the isosceles triangle 11 with the right-angled trapezoid 23 and the right-angled trapezoid 24 and a rectangle configured by a combination of the isosceles triangle 12 with the symmetrical trapezoid 23m and the symmetrical trapezoid 24m.

That is to say, in the photovoltaic power generation apparatus 1j, one isosceles triangle 11 is disposed with respect to two trapezoids (the right-angled trapezoid 23 and the right-angled trapezoid 24), and, furthermore, one isosceles triangle 12 is disposed with respect to two trapezoids (the symmetrical trapezoid 23m and the symmetrical trapezoid 24m). Thus, the triangles are isosceles triangles (the isosceles triangle 11 and the isosceles triangle 12), and the polygons are trapezoids (the right-angled trapezoid 23 and the right-angled trapezoid 24 for the isosceles triangle 11, and the symmetrical trapezoid 23m and the symmetrical trapezoid 24m for the isosceles triangle 12).

That is to say, the photovoltaic power generation elements are combined such that the number (one or two) of elements of one of the types (the second photovoltaic power generation elements 20 each in the shape of a right-angled trapezoid) is an integer multiple (twice in this example) of the number (two or four) of elements of the other type (the first photovoltaic power generation elements 10 each in the shape of an isosceles triangle), forming a rectangle.

In the photovoltaic power generation apparatus 1j, one first photovoltaic power generation element 10 is connected in parallel to two second photovoltaic power generation elements 20. Furthermore, two first photovoltaic power generation elements 10 are connected in parallel to four second photovoltaic power generation elements 20. That is to say, the photovoltaic power generation elements are connected in parallel such that the number of elements of one of the types (the second photovoltaic power generation elements 20) is an integer multiple of the number of elements of the other type (the first photovoltaic power generation elements 10).

The rectangles (the set of the isosceles triangle 11, the right-angled trapezoid 23, and the right-angled trapezoid 24, and the set of the isosceles triangle 12, the symmetrical trapezoid 23m, and the symmetrical trapezoid 24m) may be connected to each other in series.

In this embodiment, the states of the photovoltaic power generation elements (the combinations of the first photovoltaic power generation elements 10 and the second photovoltaic power generation elements 20) were described. The photovoltaic power generation apparatus array, the wafer, and the method for producing the photovoltaic power generation apparatus 1 are similar to those in Embodiments 1 to 4. Furthermore, the combination ratio of the first photovoltaic power generation elements 10 and the second photovoltaic power generation elements 20 is not limited to 1:1, and it may be 1:n (n is an integer) or n:1 for forming a rectangle. Furthermore, since all of the first photovoltaic power generation elements 10 and the second photovoltaic power generation elements 20 obtained from a single wafer are combined without waste regions to form a rectangle, and, therefore, there is no waste region formed by the division.

### <Summary>

In Embodiments 1 to 5, various types of the combinations of triangles and polygons not having less sides than a quadrangle were given as an example. FIG. 15 collectively lists exemplary combinations of triangles and polygons obtained by dividing a regular octagon.

FIG. 15 is a table that lists the contents of the combinations of triangles and polygons according to Embodiments 1 to 5.

The table shows, as examples, the case in which a rectangle is formed by combining right-angled triangles and hexagons, which are polygons, the case in which a rectangle is formed by combining right-angled triangles and pentagons, which are polygons, the case in which a rectangle is formed by combining right-angled triangles and isosceles trapezoids, which are polygons, the case in which a rectangle is formed by combining right-angled triangles and right-angled trapezoids, which are polygons, the case in which a rectangle is formed by combining isosceles triangles and isosceles trapezoids, and the case in which a rectangle is formed by combining isosceles triangles and right-angled trapezoids. A detailed description was given in each embodiment, and, therefore, it will not be repeated. Hereinafter, a summary of main configurations of the present invention will be given.

As described above, the photovoltaic power generation apparatus 1 includes the first photovoltaic power generation elements 10 each having a surface in the shape of a triangle and the second photovoltaic power generation elements 20 each having a surface in the shape of a polygon not having less sides than a quadrangle (e.g., a combination of the right-angled triangle 13 and the hexagon 25, and a combination of the isosceles triangle 11 and the isosceles trapezoid 21).

Accordingly, the photovoltaic power generation apparatus 1 is configured by a combination of the first photovoltaic power generation elements 10 each having a surface in the shape of a triangle and the second photovoltaic power generation elements 20 each having a surface in the shape of a polygon not having less sides than a quadrangle, and, therefore, the first photovoltaic power generation elements 10 and the second photovoltaic power generation elements 20 having surfaces in different shapes can be arranged such that no gap is interposed therebetween. Thus, the filling factor (laying ratio) of the light-receiving faces on the installation face can be increased by laying the first photovoltaic power generation elements 10 and the second photovoltaic power generation elements 20 having surfaces in different shapes, and the yield with respect to the circular shape CCL can be improved.

In the photovoltaic power generation apparatus 1, the first photovoltaic power generation elements 10 and the second photovoltaic power generation elements 20 are combined such that the number of elements of one of the types is the same as the number of elements of the other type (e.g., the combination of the isosceles triangle 11 and the isosceles triangle 12 with the isosceles trapezoid 21 and the isosceles trapezoid 22) or such that the number of elements of one of the types is an integer multiple of the number of elements of the other type (e.g., the combination of the hexagon 25 with the right-angled triangle 13, the symmetrical triangle 13m, the right-angled triangle 14, and the symmetrical triangle 14m), forming a rectangle.

Accordingly, since the photovoltaic power generation apparatus 1 is in the shape of a rectangle configured by a combination of the first photovoltaic power generation elements 10 and the second photovoltaic power generation elements 20 having surfaces in different shapes, the laying ratio with respect to a necessary area of the light-receiving faces can be improved by laying the first photovoltaic power generation elements 10 and the second photovoltaic power generation elements 20 with no gap interposed therebetween.

In the photovoltaic power generation apparatus 1, the triangles are isosceles triangles, and the polygons are trapezoids (e.g., the combination of the isosceles triangle 11 and the isosceles triangle 12 with the isosceles trapezoid 21 and the isosceles trapezoid 22, and the combination of the isosceles triangle 11 with the right-angled trapezoid 23 and the right-angled trapezoid 24).

Accordingly, since the photovoltaic power generation apparatus 1 is configured by a combination of isosceles triangles and trapezoids, if the trapezoids are, for example, isosceles trapezoids, the rectangle can be precisely configured by a combination of two first photovoltaic power generation elements 10 and two second photovoltaic power generation elements 20 (e.g., the combination of the isosceles trapezoid 21 and the isosceles trapezoid 22 with the isosceles triangle 11 and the isosceles triangle 12), and, if the trapezoids are, for example, right-angled trapezoids (trapezoids in which an interior angle between one leg and the lower base is a right angle), the rectangle can be precisely configured by a combination of one (or two) first photovoltaic power generation element 10 and two (or four) second photovoltaic power generation elements 20 (e.g., the combination of the right-angled trapezoid 23 and the right-angled trapezoid 24 with the isosceles triangle 11), and, therefore, an effective laying operation can be performed.

In the photovoltaic power generation apparatus 1, the triangles are right-angled triangles, and the polygons are right-angled trapezoids in which an interior angle between one leg and a lower base is a right angle (e.g., the combination of the right-angled triangle 13 and the right-angled trapezoid 24, and the combination of the right-angled triangle 14 and the right-angled trapezoid 23).

Accordingly, since the photovoltaic power generation apparatus 1 is configured by a combination of a right-angled triangle and a right-angled trapezoid in which an interior angle between one leg and the lower base (and the upper base) is a right angle, the rectangle can be configured by a combination of one (or two or four) first photovoltaic power generation elements 10 and one (or two or four) second photovoltaic power generation elements 20, and, therefore, a highly applicable and more effective laying operation can be performed using a large number of rectangles.

In the photovoltaic power generation apparatus 1, the triangles include a right-angled triangle and a symmetrical triangle, which is mirror symmetric to the right-angled triangle, and the trapezoids include a right-angled trapezoid and a symmetrical trapezoid, which is mirror symmetric to the right-angled trapezoid (e.g., the combination of the right-angled triangle 13, the symmetrical triangle 13m, the right-angled trapezoid 24, and the symmetrical trapezoid 24m).

Accordingly, since the photovoltaic power generation apparatus 1 is configured by a combination of a right-angled triangle, a symmetrical triangle, which is mirror symmetric to the right-angled triangle, a right-angled trapezoid, and a symmetrical trapezoid, which is mirror symmetric to the right-angled trapezoid, the photovoltaic power generation apparatus includes a rectangle configured by the right-angled triangle and the right-angled trapezoid and a rectangle configured by the symmetrical triangle and the symmetrical trapezoid. Thus, the symmetric properties in arrangement of the first photovoltaic power generation elements 10 and the second photovoltaic power generation elements 20 can be improved, and the unevenness in the power generation characteristics can be alleviated.

In the photovoltaic power generation apparatus 1, the triangles each have at least one interior angle that is (⅛)π radians (the interior angle θ1), and the polygons each have at least one interior angle that is (⅜)π radians (the interior angle θ₂) or (¾)π radians (the interior angle θ4), where the interior angle θ1 that is (⅛)π radians of the first photovoltaic power generation element 10 and the interior angle θ2 that is (⅜)π radians or the interior angle θ4 that is (¾)π radians of the second photovoltaic power generation element 20 are arranged adjacent to each other.

Accordingly, in the photovoltaic power generation apparatus 1, since the interior angle θ1 that is (⅛)π radians of the first photovoltaic power generation element 10 and the interior angle θ2 that is (⅜)π radians (or the interior angle θ4 that is (¾)π radians) of the second photovoltaic power generation element 20 are arranged adjacent to each other, (½)π radians (π radians) can be obtained. Thus, a precise rectangle can be configured by a combination of the first photovoltaic power generation elements 10 and the second photovoltaic power generation elements 20.

In the photovoltaic power generation apparatus 1, the first photovoltaic power generation elements 10 and the second photovoltaic power generation elements 20 are connected in parallel such that the number of elements of one of the types is the same as the number of elements of the other type (e.g., the combination of the isosceles triangle 11, the isosceles triangle 12, the isosceles trapezoid 21, and the isosceles trapezoid 22, and the combination of the right-angled triangle 13 and the right-angled trapezoid 24) or such that the number of elements of one of the types is an integer multiple of the number of elements of the other type (e.g., the combination of the hexagon 25, the right-angled triangle 13, the symmetrical triangle 13m, the right-angled triangle 14, and the symmetrical triangle 14m, the combination of the pentagon 26, the right-angled triangle 13, and the symmetrical triangle 13m, and the combination of the isosceles triangle 11, the right-angled trapezoid 23, and the right-angled trapezoid 24).

Accordingly, in the photovoltaic power generation apparatus 1, since the first photovoltaic power generation elements 10 and the second photovoltaic power generation elements 20 are connected in parallel such that the number of elements of one of the types is the same as the number of elements of the other type or such that the number of elements of one of the types is an integer multiple of the number of elements of the other type, even when the first photovoltaic power generation elements 10 and the second photovoltaic power generation elements 20 having different shapes (different light-receiving faces) are combined, the power generation amount according to the sum of their respective light-receiving areas can be obtained.

The method (the production method 1) for producing the photovoltaic power generation apparatus 1 is a production method in which the regular octagonal shape OCT is obtained by virtually combining the first photovoltaic power generation elements 10 (e.g., the right-angled triangle 13, the symmetrical triangle 13m, the right-angled triangle 14, and the symmetrical triangle 14m) each having a surface in the shape of a triangle and the second photovoltaic power generation elements 20 (e.g., the hexagon 25) each having a surface in the shape of a polygon not having less sides than a quadrangle, wherein the first photovoltaic power generation elements 10 and the second photovoltaic power generation elements 20 are formed by dividing the wafer in the regular octagonal shape OCT that has been obtained by removing in advance the waste regions SC between the regular octagonal shape OCT inscribed in the circular shape CCL and the circular shape CCL.

Thus, according to the method (the production method 1) for producing the photovoltaic power generation apparatus 1, the first photovoltaic power generation elements 10 and the second photovoltaic power generation elements 20 are formed by dividing the wafer in the regular octagonal shape OCT that has been obtained by removing in advance the waste regions SC between the circumference of the circular shape CCL and the regular octagonal shape OCT inscribed in that circumference, and, therefore, the waste regions SC do not have to be removed in each wafer. Furthermore, the division lines demarcated by vertices clearly indicate cutoffs lines, and, therefore, a photovoltaic power generation apparatus 1 in which the yield with respect to the circular shape CCL and the laying ratio are high can be precisely and easily produced.

The method (the production method 2) for producing the photovoltaic power generation apparatus 1 is a production method in which the regular octagonal shape OCT is obtained by virtually combining the first photovoltaic power generation elements 10 (e.g., the right-angled triangle 13, the symmetrical triangle 13m, the right-angled triangle 14, and the symmetrical triangle 14m) each having a surface in the shape of a triangle and the second photovoltaic power generation elements 20 (e.g., the pentagon 26 and the symmetrical pentagon 26m) each having a surface in the shape of a polygon not having less sides than a quadrangle, wherein the first photovoltaic power generation elements 10 and the second photovoltaic power generation elements 20 are formed by dividing the wafer in the circular shape CCL based on the regular octagonal shape OCT inscribed in the circular shape CCL.

Thus, according to the method for producing the photovoltaic power generation apparatus 1, the first photovoltaic power generation elements 10 and the second photovoltaic power generation elements 20 are formed by dividing the wafer in the circular shape CCL based on the regular octagonal shape OCT inscribed in the circumference of the circular shape CCL. Thus, a photovoltaic power generation apparatus 1 in which the yield is improved by suppressing the area of the waste regions SC between the circumference and the regular octagonal shape OCT, and the laying ratio is high can be precisely and easily produced.

A similar photovoltaic power generation apparatus array 1M and a similar wafer are applied in Embodiments 1 to 5.

Embodiments 1 to 5 can be applicable to each other.

The present invention may be embodied in various other forms without departing from the spirit or essential characteristics thereof. The embodiments disclosed in this application are to be considered in all respects as illustrative and not limiting. The scope of the invention is indicated by the appended claims rather than by the foregoing description. All variations and modifications falling within the meaning and range of equivalency of the appended claims are intended to be embraced therein.

What is claimed is:

1. A photovoltaic power generation apparatus, comprising:
a first photovoltaic power generation element having a surface in a shape of a triangle; and
a second photovoltaic power generation element having a surface in a shape of a polygon not having less sides than a quadrangle.

2. The photovoltaic power generation apparatus according to claim 1, wherein the first photovoltaic power generation element and the second photovoltaic power generation element are combined such that the number of elements of one of the types is the same as the number of elements of the other type, or combined such that the number of elements of one of the types is an integer multiple of the number of elements of the other type, forming a rectangle.

3. The photovoltaic power generation apparatus according to claim 1, wherein the first photovoltaic power generation element and the second photovoltaic power generation element are connected in parallel such that the number of elements of one of the types is the same as or is an integer multiple of the number of elements of the other type.

4. The photovoltaic power generation apparatus according to claim 1, wherein the triangle has at least one interior angle that is (⅛)π radians, and the polygon has at least one interior angle that is (⅜)π radians or (¾)π radians, and
the interior angle that is (⅛)π radians of the first photovoltaic power generation element and the interior angle that is (⅜)π radians or (¾)π radians of the second photovoltaic power generation element are arranged adjacent to each other.

5. The photovoltaic power generation apparatus according to claim 1, wherein the triangle is an isosceles triangle, and the polygon is a trapezoid.

6. The photovoltaic power generation apparatus according to claim 1, wherein the triangle is a right-angled triangle, and the polygon is a right-angled trapezoid in which an interior angle between one leg and a lower base is a right angle.

7. The photovoltaic power generation apparatus according to claim 6, wherein the triangle includes the right-angled triangle and a symmetrical triangle, which is mirror symmetric to the right-angled triangle, and the polygon includes the right-angled trapezoid and a symmetrical trapezoid, which is mirror symmetric to the right-angled trapezoid.

8. The photovoltaic power generation apparatus according to claim 1, wherein the first photovoltaic power generation element and the second photovoltaic power generation element are of a back-face electrode type, and connected to a wiring board.

9. A photovoltaic power generation apparatus array in which a plurality of photovoltaic power generation apparatuses are connected in an array, wherein the photovoltaic power generation apparatuses are each the photovoltaic power generation apparatus according to claim 1.

10. A wafer having a surface in a shape of a regular octagon cut out from a circular shape.

11. A method for producing the photovoltaic power generation apparatus according to claim 1 in which a regular octagonal shape is obtained by virtually combining a first photovoltaic power generation element having a surface in a shape of a triangle and a second photovoltaic power generation element having a surface in a shape of a polygon not having less sides than a quadrangle,
wherein the first photovoltaic power generation element and the second photovoltaic power generation element are formed by dividing a wafer in the regular octagonal shape that has been obtained by removing in advance waste regions between the regular octagonal shape inscribed in a circular shape and the circular shape.

12. A method for producing the photovoltaic power generation apparatus according to claim 1 in which a regular octagonal shape is obtained by virtually combining a first photovoltaic power generation element having a surface in a shape of a triangle and a second photovoltaic power generation element having a surface in a shape of a polygon not having less sides than a quadrangle,
wherein the first photovoltaic power generation element and the second photovoltaic power generation element are formed by dividing a wafer in a circular shape based on the regular octagonal shape inscribed in the circular shape.
